(19) United States
(12) Patent Application Publication
(10) Pub. No.: US 2025/0022826 A1
(43) Pub. Date: Jan. 16, 2025

(54) SOLDER BALL ATTACHMENT SYSTEM AND METHOD FOR PREVENTING WARPAGE

(71) Applicant: PEP INNOVATION PTE. LTD, Singapore (SG)

(72) Inventor: Hwee Seng Chew, Singapore (SG)

(73) Assignee: PEP INNOVATION PTE. LTD, Singapore (SG)

(21) Appl. No.: 18/771,828

(22) Filed: Jul. 12, 2024

(30) Foreign Application Priority Data
Jul. 14, 2023 (SG) 10202302015Y

(51) Int. Cl. H01L 23/00; H01L 21/677; H01L 21/683; H01L 25/00

(52) U.S. Cl. CPC H01L 24/11; H01L 24/742; H01L 24/96; H01L 25/50; H01L 21/67703; H01L 21/6838; H01L 2224/1112; H01L 2224/1181; H01L 2224/11849; H01L 2224/742; H01L 2224/95144

(57) ABSTRACT

The present application discloses a solder ball attachment jig for preventing warpage of a reconstructed panel in a panel-level semiconductor process, a solder ball attachment system including the solder ball attachment jig, and a method of preventing warpage in attaching solder balls for a panel-level semiconductor process with the solder ball attachment jig. The solder ball attachment jig includes a platform having at least one ejector, and a plate carrier configured to be coupled to the platform for carrying and fixing the reconstructed panel with a plurality of semiconductor dies and a warpage-preventing device. The plate carrier further includes a base plate and at least one releasing hole extending through the base plate, wherein the at least one ejector is configured to be inserted through the at least one releasing hole for releasing the reconstructed panel from the solder ball attachment jig.

### CROSS-REFERENCE TO RELATED APPLICATIONS

This application claims the benefit of Singapore Provisional Applications No. 10202302015Y filed on 14 Jul. 2023, the disclosure of which is herein incorporated by reference in its entirety for all purposes.

### TECHNICAL FIELD

The present application relates to a solder ball attachment system for forming solder balls for semiconductor packages; and particularly relates to a solder ball attachment jig for preventing warpage of a reconstructed panel in a panel-level semiconductor process. The present application further relates to a method of preventing warpage for attaching solder balls in the panel-level semiconductor process and a reconstructed panel made therefrom.

### BACKGROUND

Current solder ball attachment technologies face a serious challenge of warpage to a reconstructed panel in a panel-level semiconductor process. The warpage would negatively affect electrical connections of semiconductor packages made from the reconstructed panel, particularly for Ball Grid Array (BGA) semiconductor packages when solder balls are adopted as the electrical connections to external devices such as Printed Circuit Board (PCB).

Therefore, the present application discloses a solder ball attachment system (including a solder ball attachment jig) for preventing warpage of the reconstructed panel in a panel-level semiconductor process; as well as a method of preventing warpage for attaching solder balls in the panel-level semiconductor process with the solder ball attachment system and a reconstructed panel made with the solder ball attachment system and the method thereof.

### SUMMARY

As a first aspect, the present application discloses a solder ball attachment jig for preventing warpage of a reconstructed panel in a panel-level semiconductor process. The solder ball attachment jig includes a platform having at least one ejector, and a plate carrier configured to be coupled to the platform for carrying and fixing the reconstructed panel with a plurality of semiconductor dies and a warpage-preventing device. The plate carrier further includes a base plate and at least one releasing hole extending through the base plate, wherein the at least one ejector is configured to be inserted through the at least one releasing hole for releasing the reconstructed panel from the solder ball attachment jig.

As a second aspect, the present application discloses a solder ball attachment system for preventing warpage of a reconstructed panel in a panel-level semiconductor process. The solder ball attachment system includes the solder ball attachment jig described in the first aspect, a flux station for applying flux to the reconstructed panel, a placement station for placing the solder balls to the reconstructed panel, an inspection station for inspecting the solder balls on the reconstructed panel, a reflow station for reflowing the solder balls on the reconstructed panel, a cleaning station for removing the flux from the reconstructed panel, a releasing station for releasing the reconstructed panel and the solder balls from the solder ball attachment jig, and a conveyor for conveying the reconstructed panel on the solder ball attachment jig among the flux station, the placement station, the inspection station, the reflow station, the cleaning station and the releasing station.

As a third aspect, the present application discloses a method of preventing warpage in attaching solder balls for a panel-level semiconductor process. The method includes forming a reconstructed panel having a warpage-preventing device, mounting the reconstructed panel onto a solder ball attachment jig as described in the first aspect, attaching the solder balls onto the reconstructed panel, and releasing the reconstructed panel and the solder balls from the solder ball attachment jig. The warpage-preventing force is applied by the warpage-preventing device against the warpage of the reconstructed panel.

### BRIEF DESCRIPTION OF THE DRAWINGS

The accompanying figures (Figs.) illustrate embodiments and explain principles of the disclosed embodiments. It is to be understood, however, that these figures are presented for purposes of illustration only, and not for defining limits of relevant applications.

FIG. 1 illustrates a flow chart of a method of preventing warpage in attaching solder balls for the panel-level semiconductor process, as described in the present disclosure.

FIG. 2 illustrates a flow chart of Step S12 of the method shown in FIG. 1.

FIGS. 3a & 3b illustrate sub-step S121 of Step S12.

FIGS. 4a & 4b illustrate sub-step S122 of Step S12.

FIG. 5 illustrates a first process of sub-step S123 of Step S12.

FIGS. 6a & 6b illustrate a second process of sub-step S123 of Step S12.

FIGS. 7a to 7d illustrate sub-step S124 of Step S12.

FIGS. 8a to 8d illustrate sub-step S125 of Step S12.

FIG. 9 illustrates a diagram of a solder ball attachment system according of the method shown in FIG. 1.

FIGS. 10a to 10d illustrate two exemplary embodiments of a solder ball attachment jig.

FIGS. 11a to 11n illustrate Step S14 of the method shown in FIG. 1.

FIGS. 12a to 12i illustrate Step S16 of the method shown in FIG. 1 with the solder ball attachment system in FIG. 9.

FIGS. 13a to 13c illustrate Step S18 of the method shown in FIG. 1 with the solder ball attachment system in FIG. 9.

FIGS. 14a to 14c illustrate Step S20 of the method shown in FIG. 1 with the solder ball attachment system in FIG. 9.

FIGS. 15a to 15c illustrate discrete semiconductor packages after the Step S20.

FIGS. 16a & 16b illustrate another embodiment of Step S14.

FIGS. 17a & 17b illustrate another embodiment of Step S14.

FIGS. 18a & 18b illustrate combinations of the embodiments in the above figures.

FIGS. 19a to 19e illustrate a process of applying flux to the reconstructed panel in FIG. 12a.

### DETAILED DESCRIPTION OF THE INVENTION

FIG. 1 illustrates a flow chart of a method S10 of preventing warpage in attaching solder balls for the panel-level semiconductor process according to an exemplary embodiment of the present disclosure. Prevention or elimination of the warpage would improve reliability of semiconductor packages (such as Ball Grid Array (BGA) semiconductor packages) for electrical connections such as to external devices. The method S10 includes Steps S12, S14, S16, S18 and S20 as described in the present disclosure.

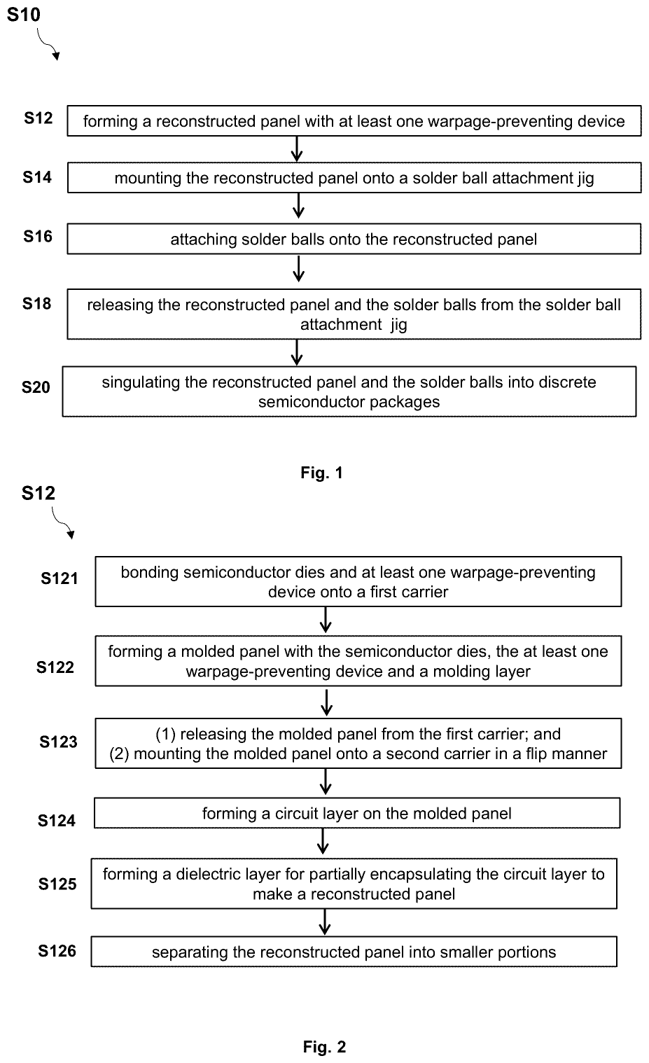

FIG. 2 illustrate a flow chart of Step S12 of method S10, which forms a reconstructed panel 290 with one or more warpage-preventing devices 210. Step S12 includes sub-steps S121, S122, S123, S124, S125 and S126 as described in the present disclosure.

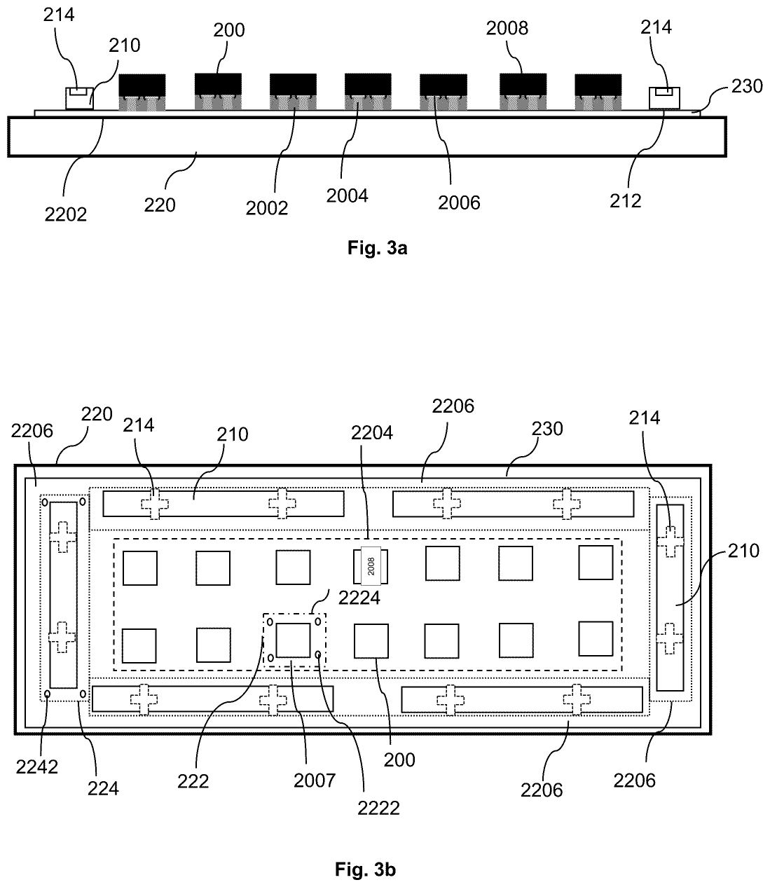

FIG. 3a shows a cross-sectional view of the sub-step S121, bonding the semiconductor dies 200 and the one or more warpage-preventing devices 210 onto the first carrier 220. Particularly, the semiconductor dies 200 are bonded in a face-down manner, i.e., an active surface 2002 of the semiconductor die 200 is in contact with a front surface 2202 of the first carrier 220. The active surface 2002 has pre-vias 2004 for exposing contact pads 2006 of the semiconductor die 200. The semiconductor die 200 has an inactive surface 2008 opposed to the active surface 2002 and far away from the first carrier 220. The warpage-preventing device 210 also has a first surface 212 in contract with the front surface 2202 of the first carrier 220. The semiconductor die 200 may be bonded first before the warpage-preventing device 210; or the warpage-preventing device 210 may be bonded first before the semiconductor die 200, or the semiconductor die 200 and the warpage-preventing device 210 may be bonded alternatively onto the first carrier 220. In addition, a first heat release tape 230 may be attached between the first carrier 220 and the semiconductor dies 200 and the warpage-preventing device 210. The first heat release tape 230 on the one hand can be secured to the front surface 2202 of the first carrier 220; and on the other hand, can secure the semiconductor dies 200 and the warpage-preventing device 210 bonded on the first carrier 220.

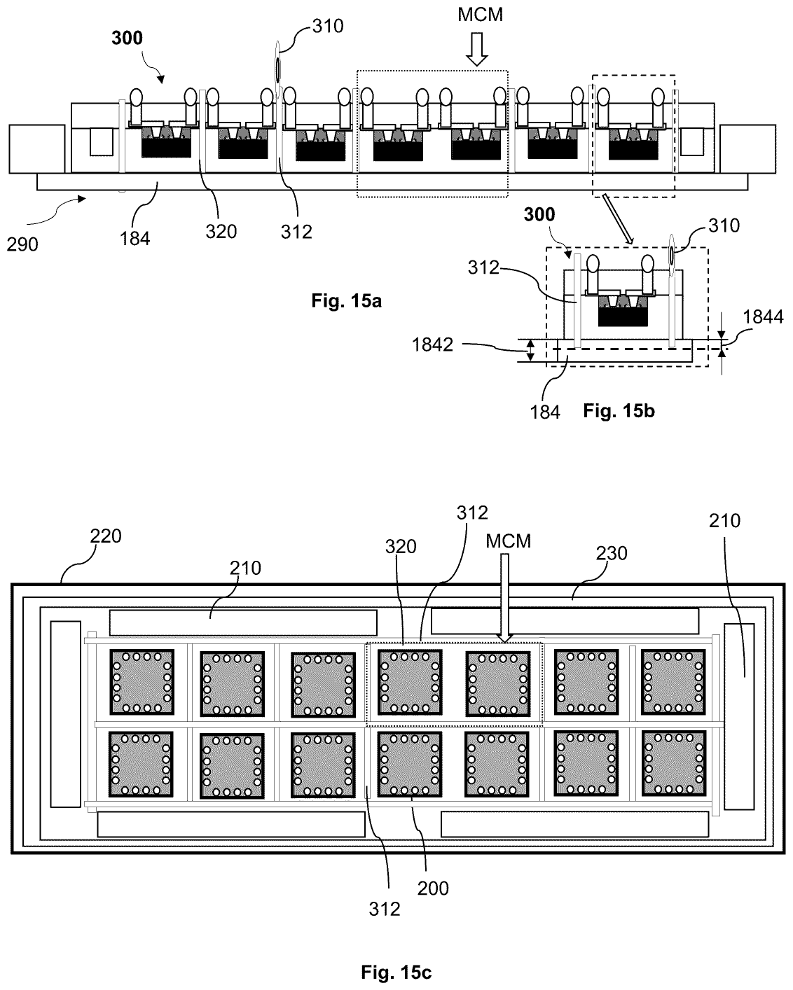

FIG. 3b shows a top view of a portion of the first carrier 220 with the semiconductor dies 200 and the warpage-preventing device 210 bonded onto the first carrier 220. It is shown that the semiconductor dies 200 and the warpage-preventing device 210 are bonded at a central location 2204 (as indicated by a dashed rectangle) and peripheries 2206 of the first carrier 220 respectively. The first carrier 220 has many die bonding units 222 (as indicated by a dotted-dashed square) each of which would accommodate one of the semiconductor dies 200. The semiconductor die 200 has a die profile 2007 significantly smaller than a die bonding unit profile 2224 of the die bonding unit 222 for making a fan-out semiconductor package where a package profile 320 (see FIG. 15a & 15c) of the fan-out semiconductor package is also larger than the die profile 2007 of the semiconductor die 200. However, it is understood that the method S10 can be also adopted for making a fan-in semiconductor package where the die profile 2007 of the semiconductor die 200 may be slightly smaller than the die bonding unit profile 2224 of the die bonding unit 222 so that the semiconductor die 200 can be closely arranged on the first carrier 220. In a preferred embodiment, the semiconductor dies 200 and the warpage-preventing device 210 are bonded in a symmetric manner for maintaining balance of the semiconductor dies 200 and the warpage-preventing device 210 on the first carrier 220 to facilitate prevention of the warpage in the solder ball attachment process. It is understood that the first carrier 220 may have any shape and dimension by including one or more of the portions shown in FIG. 3b. In a preferred embodiment, the first heat release tape 230 is transparent or semi-transparent for observing the die bonding unit 222 on the front surface 2202 of the first carrier 220 more conveniently.

The die bonding unit 222 may also have carrier marks 2222 for guiding the semiconductor die 200 to be bonded precisely as designed into the die bonding unit 222. FIG. 3b shows that 4 carrier marks 2222 are located at 4 corners of the die bonding unit 222 respectively. Before bonding the semiconductor die 200 onto the first carrier 220, die features of the semiconductor die 200 (such as the pre-vias 2004 at the active surface 2002) are identified; then the semiconductor die 200 is placed to the die bonding unit 222 precisely as designed by aligning the die features of the semiconductor die 200 to the carrier marks 2222; and finally, the semiconductor die 200 are bonded to the die bonding unit 222 accordingly. It is understood that FIG. 3b shows an exemplary embodiment only; and the die bonding unit 222 may have other numbers and arrangements of the carrier marks 2222 according to the die features of the semiconductor die 200.

Similarly, the first carrier 220 may also have warpage-preventing device bonding units 224 (as indicated by dotted rectangles in FIG. 3b) each of which would accommodate one or more of the warpage-preventing devices 210. The warpage-preventing device bonding unit 224 may have warpage-preventing carrier marks 2242 for guiding the warpage-preventing device 210 to be bonded precisely as designed into the warpage-preventing device bonding unit 224. Before bonding the warpage-preventing device 210 onto the first carrier 220, warpage-preventing device features (such as crosses 214 shown in FIG. 3b) of the warpage-preventing device 210 are identified; then the warpage-preventing device 210 is placed to the warpage-preventing device bonding unit 224 precisely as designed by aligning the warpage-preventing device features of the warpage-preventing device 210 to the warpage-preventing carrier marks 2242; and finally, the warpage-preventing device 210 are bonded into the warpage-preventing device bonding unit 224 accordingly. It is understood that the warpage-preventing device bonding unit 224 may have other numbers and arrangements of the warpage-preventing carrier marks 2242 according to the warpage-preventing device features of the warpage-preventing device 210. The die bonding unit 222, the carrier marks 2222, the warpage-preventing device bonding unit 224, the warpage-preventing carrier marks 2242 and the crosses 214 (as the warpage-preventing device features) are skipped in the following figures for simple illustration.

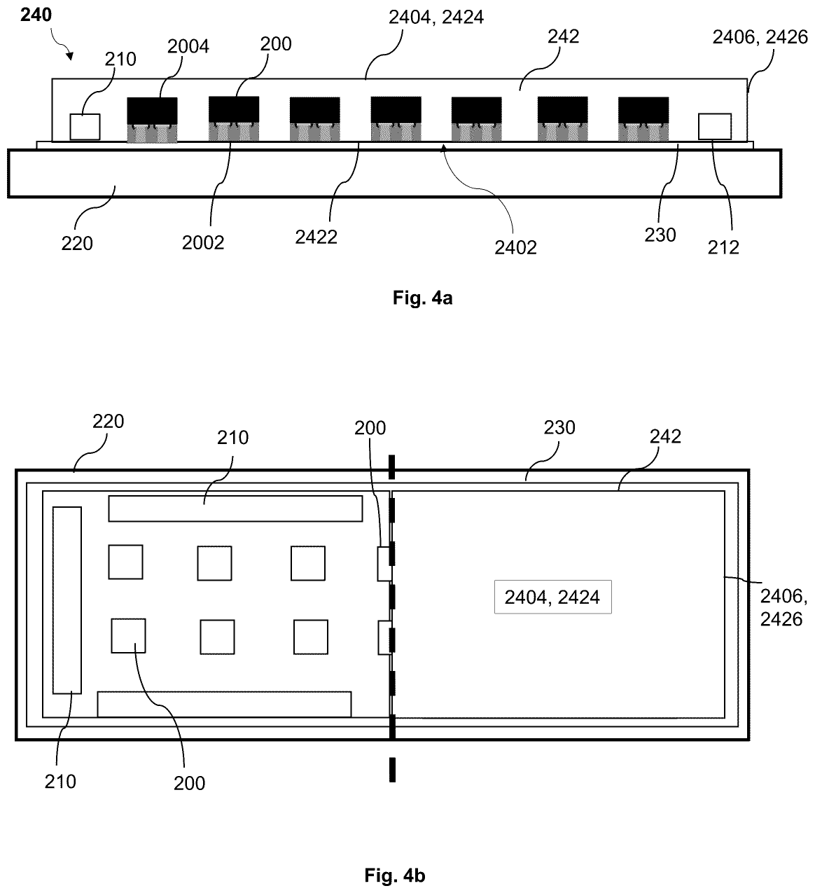

FIGS. 4a & 4b illustrate the sub-step S122 of the Step S12, forming a molded panel 240 with the semiconductor die 200, the warpage-preventing device 210 and a molding layer 242 on the first carrier 220. The molding layer 242 is formed in a molding process with a molding material which would creep into spaces between the semiconductor dies 200 and the warpage-preventing device 210 and then get in contact with the first heat release tape 230. In an embodiment, the molding layer 242 is formed in a compression molding process conducted at a high temperature (such as at around 140° C.) and at a high pressure (such as at around 6 Megapascal (MPa)) with the molding compound G730.

FIG. 4a shows a cross-sectional view that the semiconductor dies 200 and the warpage-preventing device 210 are encapsulated inside the molding layer 242. The molding layer 242 has an active surface 2422 in contact with the first heat release tape 230 and a back surface 2424 opposed to the active surface 2422. Accordingly, the molded panel 240 has an active side 2402 which includes the active surface 2002 of the semiconductor die 200, the first surface 212 of the warpage-preventing device 210 and the active surface 2422 of the molding layer 242; while the back surface 2424 constitutes a back side 2404 of the molded panel 240. In addition, the molding layer 242 has molded layer edges 2426 for constituting molded panel edges 2406 for defining a planar dimension of the molded panel 240. FIG. 4b shows a perspective view on the left side and a top view on the right side, separated by a vertical dashed line. The perspective view shows that the semiconductor dies 200 and the warpage-preventing devices 210 are kept in place within tolerance during the molding process; and the top view shows that the semiconductor dies 200 and the warpage-preventing devices 210 are completely encapsulated inside the molding layer 242 and only the back surface 2424 of the molding layer 242 (or the back side 2404 of the molded panel 240) is seen.

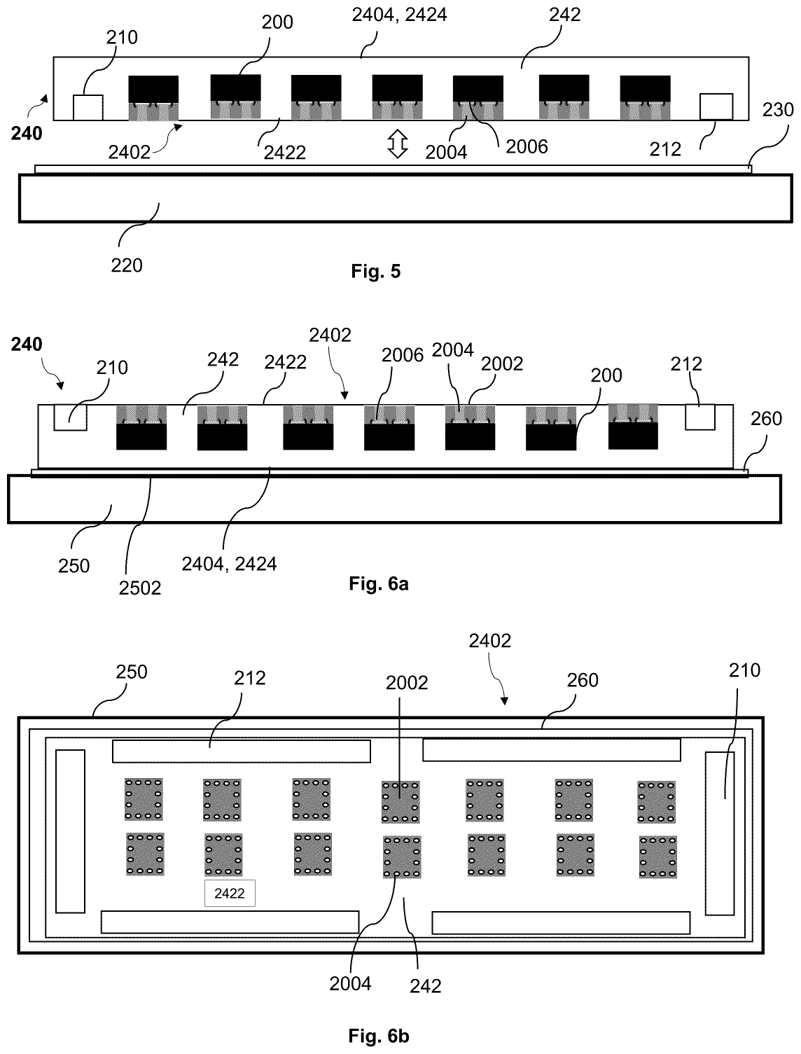

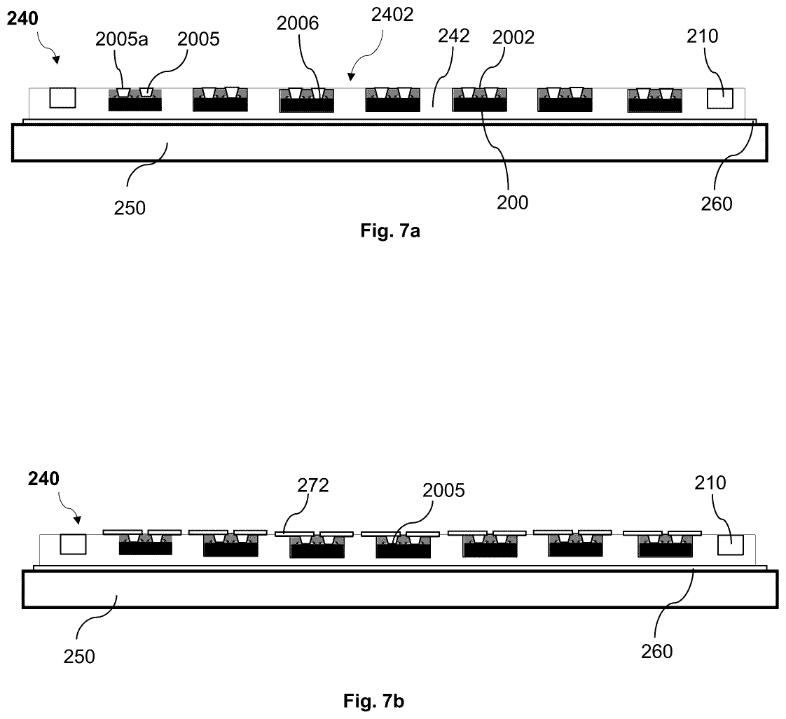

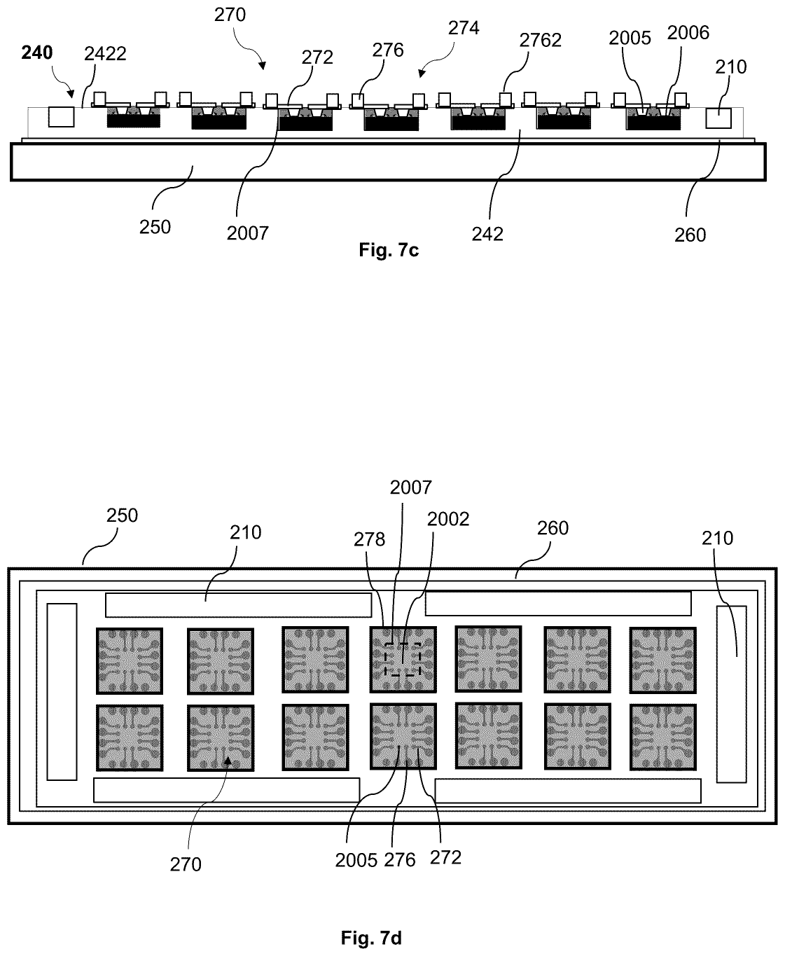

FIG. 5 illustrates a first process of the sub-step S123 of the Step S12 in a cross-sectional view, releasing the molded panel 240 from the first carrier 220. The molded panel 240 would be released from the first carrier 220 and the first heat release tape 230 since the first heat release tape 230 would lose adhesivity under an elevated temperature (such as at around 200° C.). After being released, the active side 2402 of the molded panel 240 is exposed from the first heat release tape 230 and the first carrier 220. Accordingly, the contact pads 2006 of the semiconductor die 200 are exposed from the active side 2402 of the molded panel 240 through the pre-vias 2004. Then, the molded panel 240 would be flipped upside-down, i.e., the active side 2402 of the molded panel 240 faces upwardly, so that a circuit layer 270 (see FIGS. 7a & 7b) can be formed on the active side 2402 of the molded panel 240 in the following processes.

FIGS. 6a & 6b illustrate a second process of sub-step S123 of Step S12, mounting the molded panel 240 onto a second carrier 250 in a flip manner, i.e., the back side 2404 of the molded panel 240 (or the back surface 2424 of the molding layer 242) is in contact with a front surface 2502 of the second carrier 250. FIG. 6a shows a cross-sectional view that the active surface 2002 of the semiconductor die 200 is exposed from the active surface 2422 of the molding layer 242; and accordingly, the contact pads 2006 of the semiconductor die 200 can be exposed through the pre-vias 2004 for forming the circuit layer 270 which would be electrically coupled to the contact pads 2006. The first surface 212 of the warpage-preventing device 210 is also exposed from the active surface 2422 of the molding layer 242, but the circuit layer 270 would not be formed thereon. In addition, a second heat release tape 260 may be attached between the second carrier 250 and the molded panel 240, i.e., the second heat release tape 260 is in contact with the front surface 2502 of the second carrier 250 and the back side 2404 of the molded panel 240. Similar to the first heat release tape 230, the second heat release tape 260 can be secured to the front surface 2502 of the second carrier 250 and can also secure the molded panel 240 mounted on the second carrier 250. FIG. 6b shows a top view of the active side 2402 of the molded panel 240. The active surface 2002 (including the pre-vias 2004) of the semiconductor die 200 and the first surface 212 of the warpage-preventing device 210 are exposed from the active surface 2422 of the molding layer 242; and then the circuit layer 270 would be formed on the exposed active surface 2002 of the semiconductor die 200 accordingly.

FIGS. 7a to 7d illustrate the sub-step S124 of the Step S12, forming the circuit layer 270 on the active surface 2002 of the semiconductor die 200. Circuit layer 270 includes a redistribution layer (RDL) 272 and a stud layer 274. FIG. 7a shows a cross-sectional view of filling the pre-vias 2004 of the semiconductor die 200 with a conductive material such as Copper (Cu) to form filled vias 2005. Accordingly, the filled vias 2005 are electrically coupled to the contact pads 2006 of the semiconductor die 200 for leading out the semiconductor die 200 to external devices such as PCB. In a preferred embodiment, the filled vias 2005 have a filled top surface 2005a co-planar with the active surface 2002 of the semiconductor die 200, so that the active side 2402 is kept flat for facilitating formation of the RDL 272 in the next step.

FIG. 7b shows a cross-sectional view of forming the RDL 272 on the active surface 2002 of the semiconductor die 200; and the RDL 272 is in contact with the filled vias 2005. A thin composite layer of Titanium and Copper (Ti/Cu) may be formed first on the active side 2402 of the molded panel 240 (including the filled top surface 2005a of the filled vias 2005) as a seed layer (not shown) according to a design of the circuit layer 270; and then a photographic process is performed to form the RDL 272 on the seed layer. Since the seed layer has better chemical compatibility with the RDL 272, the RDL 272 could be more securely formed on the active side 2402 of the molded panel 240. Accordingly, the RDL 272 is electrically coupled to the filled vias 2005 and the contact pads 2006 of the semiconductor die 200. The RDL 272 also extends beyond the die profile 2007 of the semiconductor die 200 and onto the active surface 2422 of the molding layer 242 for making the fan-out semiconductor packages.

FIG. 7c shows a cross-sectional view of forming the stud layer 274 on and electrically coupled to the RDL 272. The stud layer 274 includes studs 276 formed outside the die profile 2007 of the semiconductor die 200 for making the fan-out semiconductor packages. It is understood that the method S10 is also applicable to the fan-in semiconductor package where the RDL 272 and the studs 276 of the stud layer 274 are formed within the die profile 2007 of the semiconductor die 200. For either the fan-out semiconductor package or the fan-in semiconductor package, the semiconductor die 200 can be led out from the contact pads 2006, through the filled vias 2005, the RDL 272 and the stud layer 274 of the circuit layer 270 to external devices such as PCB. FIG. 7d shows a top view that the circuit layer 270, the active surface 2002 of the semiconductor die 200 (not covered by the circuit layer 270) and the first surface 212 of the warpage-preventing device 210 are exposed from the active surface 2422 of the molding layer 242. It is also shown that the die profile 2007 (as indicated by a dashed square) is within a circuit profile 278 of the circuit layer 270. The circuit profile 278 is defined by the extension of the RDL 272 for the fan-out semiconductor package. While for the fan-in semiconductor package, the circuit profile 278 would be within the die profile 2007 of the semiconductor die 200 since the RDL 272 would not extend beyond the die profile 2007 of the semiconductor die 200.

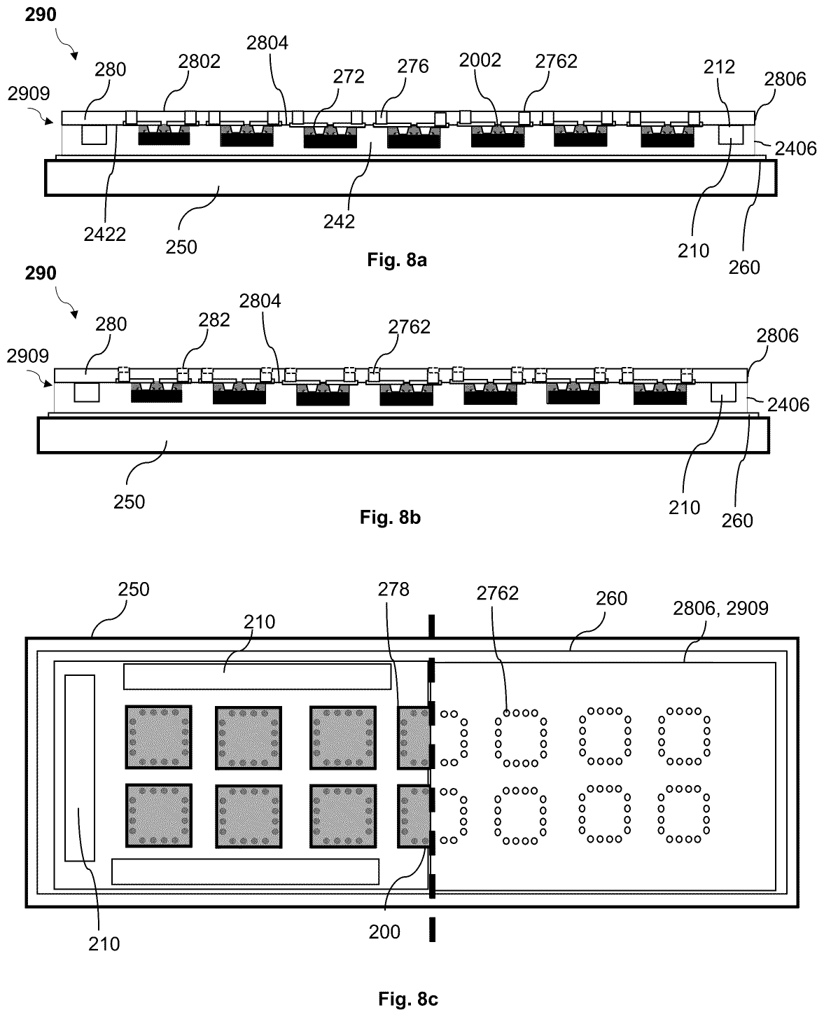

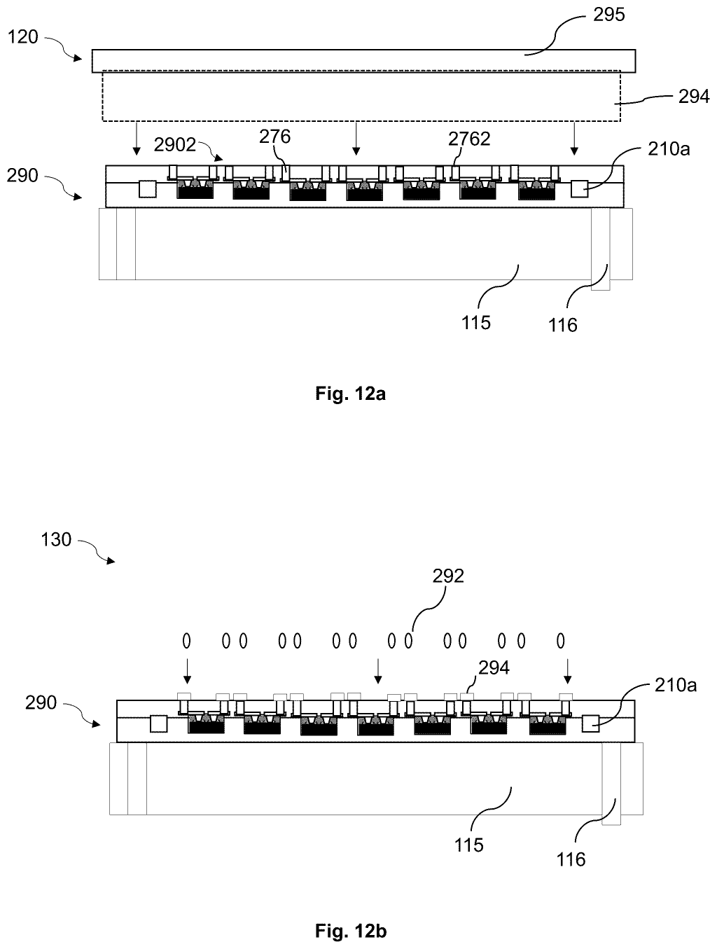

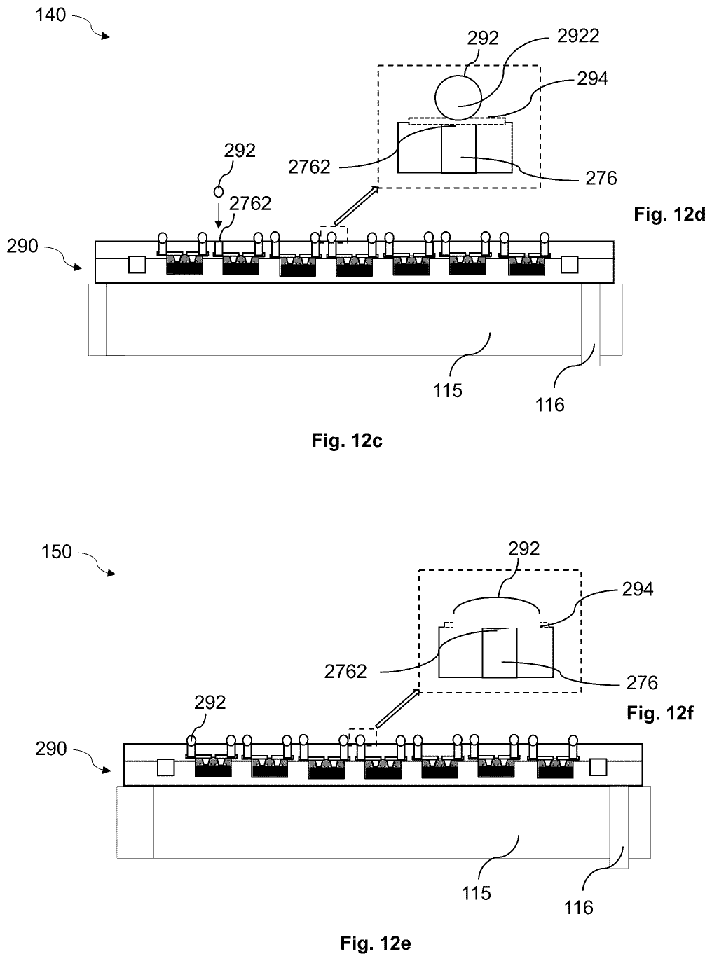

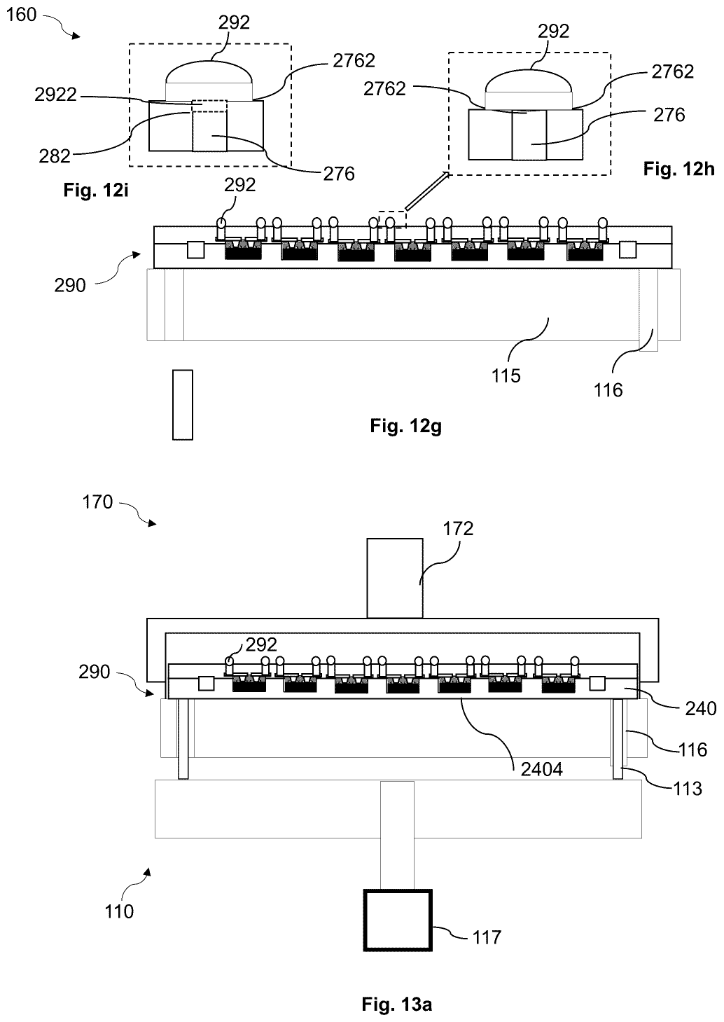

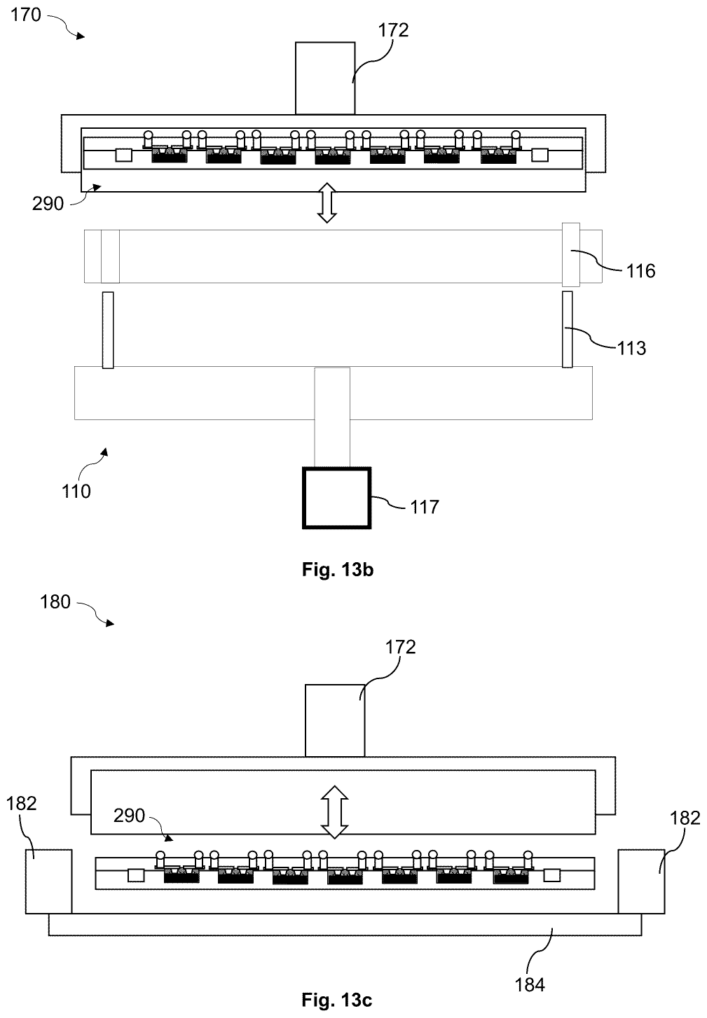

FIGS. 8a to 8c illustrate the sub-step S125 of the Step S12, forming a dielectric layer 280 for partially encapsulating the circuit layer 270 to make the reconstructed panel 290. A top stud surface 2762 of the studs 276 is exposed from the dielectric layer 280. As an embodiment, FIG. 8a shows a cross-sectional view that the top stud surface 2762 of the studs 276 is co-planar with a top dielectric surface 2802 of the dielectric layer 280. The dielectric layer 280 also has a bottom dielectric surface 2804 opposed to the top dielectric surface 2802 of the dielectric layer 280. The bottom dielectric surface 2804 of the dielectric layer 280 is in contact with the active surface 2422 of the molding layer 242. In addition, the dielectric layer 280 has dielectric layer edges 2806 for defining a planar dimension of the dielectric layer 280. As shown in FIG. 8a, the molded panel edge 2406 of the molded panel 240 and the dielectric layer edges 2806 of the dielectric layer 280 are aligned for forming a reconstructed panel edge 2909. In an embodiment, the molded panel edges 2406 of the molded panel 240 and the dielectric layer edges 2806 of the dielectric layer 280 are co-planar for the reconstructed panel edges 2909 of the reconstructed panel 290. In another embodiment, FIG. 8b shows a cross-sectional view that cavities 282 are formed in the dielectric layer 280 above the studs 276, so that the top stud surface 2762 of the studs 276 is exposed from the cavities 282. Since solder balls 292 would flow into the cavities 282 during a reflow process (see FIG. 12i), the solder balls 292 (see FIGS. 13a & 13b) could be more firmly secured at the studs 276. Therefore, the reconstructed panel 290 is formed including the molded panel 240, the circuit layer 270 and the dielectric layer 280.

FIG. 8c shows a perspective view on a left side and a top view on a right side of the reconstructed panel 290 as separated by a dashed line. The perspective view shows that the semiconductor dies 200 and the warpage-preventing devices 210 in the molded panel 240 are kept in place during the formation of the circuit layer 270 and the dielectric layer 280. The top view shows that the circuit layer 270 is encapsulated by the dielectric layer 280 except the top stud surface 2762 of the studs 276 which are exposed for receiving the solder balls 292. As stated above, FIG. 3b shows the portion of the first carrier 220; therefore, FIG. 8c shows a portion of the reconstructed panel 290 in accordance to the portion of the first carrier 220 in FIG. 3b. The portion of the reconstructed panel 290 shown in FIG. 8c may have a dimension of 212 millimeters×216 millimeters (mm) known as a strip panel.

FIG. 8d illustrates the sub-step S126 of the Step S12, separating the reconstructed panel 290 into smaller portions such as the strip panels. FIG. 8d shows a perspective view that the reconstructed panel 290 includes 3 of the smaller portions shown in FIG. 8c, i.e., a first portion 2902 as indicated by a first dashed rectangle 2901, a second portion 2904 as indicated by a second dashed rectangle 2903, and a third portion 2906 as indicated by a third dashed rectangle 2905. The first, second and third portions 2902, 2904, 2906 have a first warpage-preventing device 2102, a second warpage-preventing device 2104 and a third warpage-preventing device 2106. The reconstructed panel 290 may be separated into the 3 portions 2902, 2904, 2906 along a first separation street 2907 and a second separation street 2908. Since the reconstructed panel 290 has a much larger size than each of the 3 portions 2902, 2904, 2906, the warpage to the reconstructed panel 290 is significantly more severe than each of the 3 portions 2902, 2904, 2906. Therefore, the warpage would be greatly reduced if the solder ball attachment would be performed to each of the 3 portion 2902, 2904, 2906 individually, compared to being performed to the reconstructed panel 290 as a whole. It is understood that the reconstructed panel 290 may have 4 or more of the portions which have smaller sizes than the portions 2902, 2904, 2906 for further reducing the warpage. However, it is also understood that the more portions the reconstructed panel 290 is separated into, the less the semiconductor die 200 could be included; and the less efficiency would be for making the semiconductor packages.

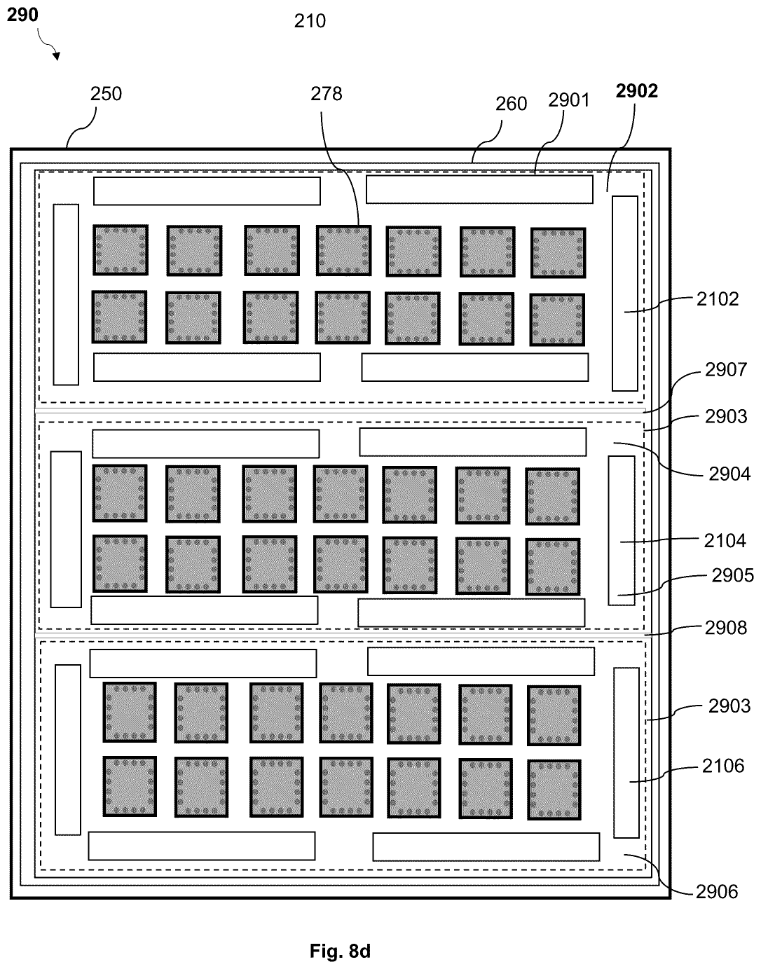

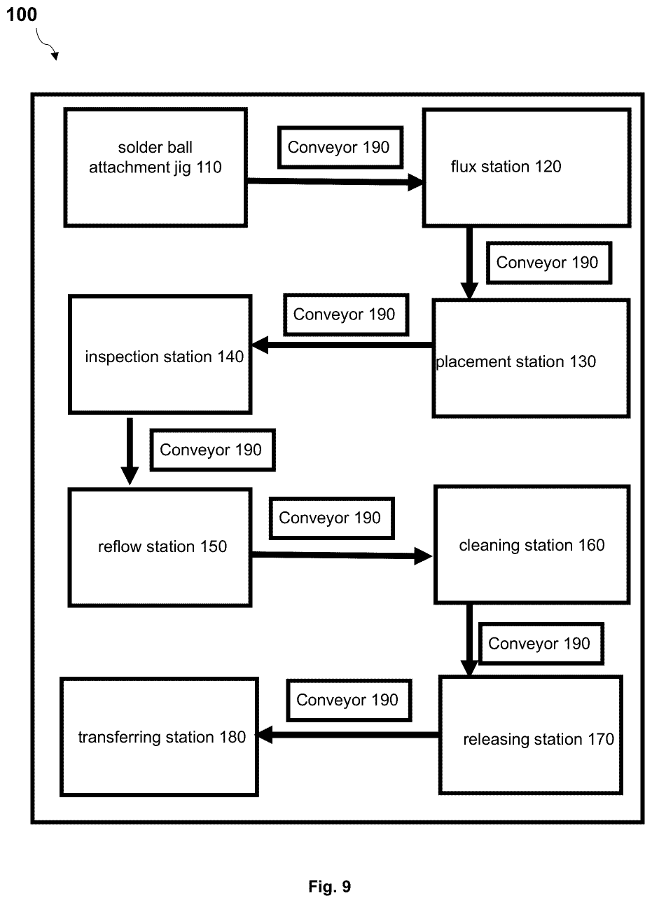

FIG. 9 illustrates a diagram of a solder ball attachment system 100 according to the method S10. The solder ball attachment system 100 has a solder ball attachment jig 110 for carrying and fixing the reconstructed panel 290 and also for preventing warpage of the reconstructed panel 290 during the attachment of the solder balls 292 to the studs 276 of the constructed panel 290. The solder ball attachment system 100 may also have a flux station 120 for applying flux at the top stud surface 2762 of the studs 276 exposed from the dielectric layer 280, a placement station 130 for placing (such as by a means of dropping) the solder balls 292 to the flux remaining at the top stud surface 2762 of the studs 276, an inspection station 140 for inspecting whether the solder balls 292 are correctly placed at the top stud surface 2762 of the studs 276, a reflow station 150 for reflowing the solder balls 292 (where the solder balls 292 are melt and fused at an elevated temperature) to the top stud surface 2762 of the studs 276, a cleaning station 160 for removing residual flux from the reconstructed panel 290, a releasing station 170 for releasing the reconstructed panel 290 and the solder balls 292 from the solder ball attachment jig 110, and a transferring station 180 for transferring the reconstructed panel 290 and the solder balls 292 onto a wafer ring 182 for singulation. In addition, the solder ball attachment system 100 may have a conveyor 190 for conveying the reconstructed panel 290 among the solder ball attachment jig 110 and all the stations 120-180 described above. Conveyor 190 may include a transport belt, a walking beam, an indexing table or any combination thereof.

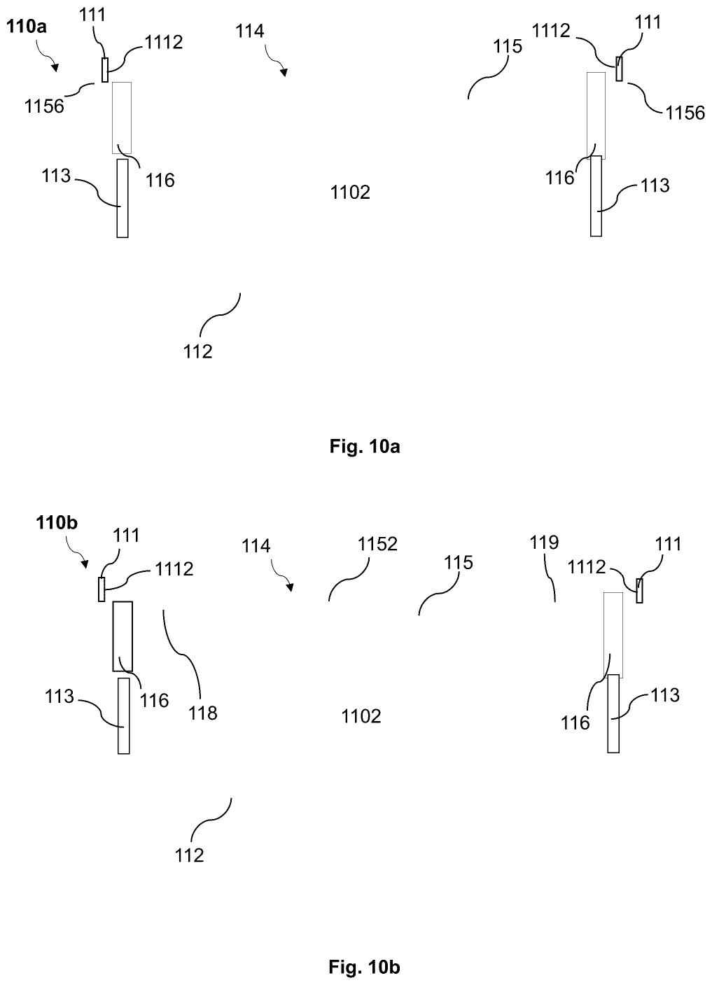

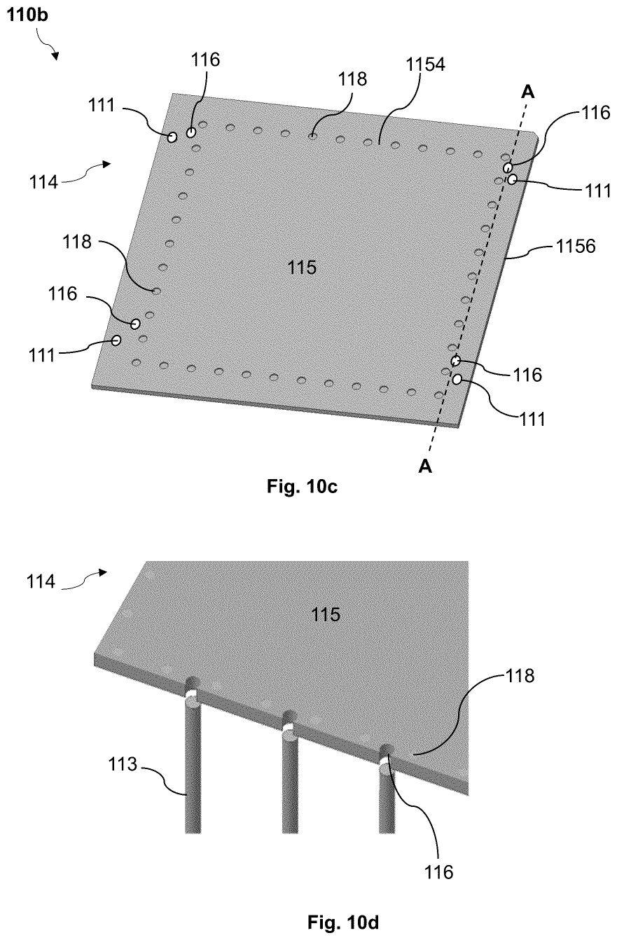

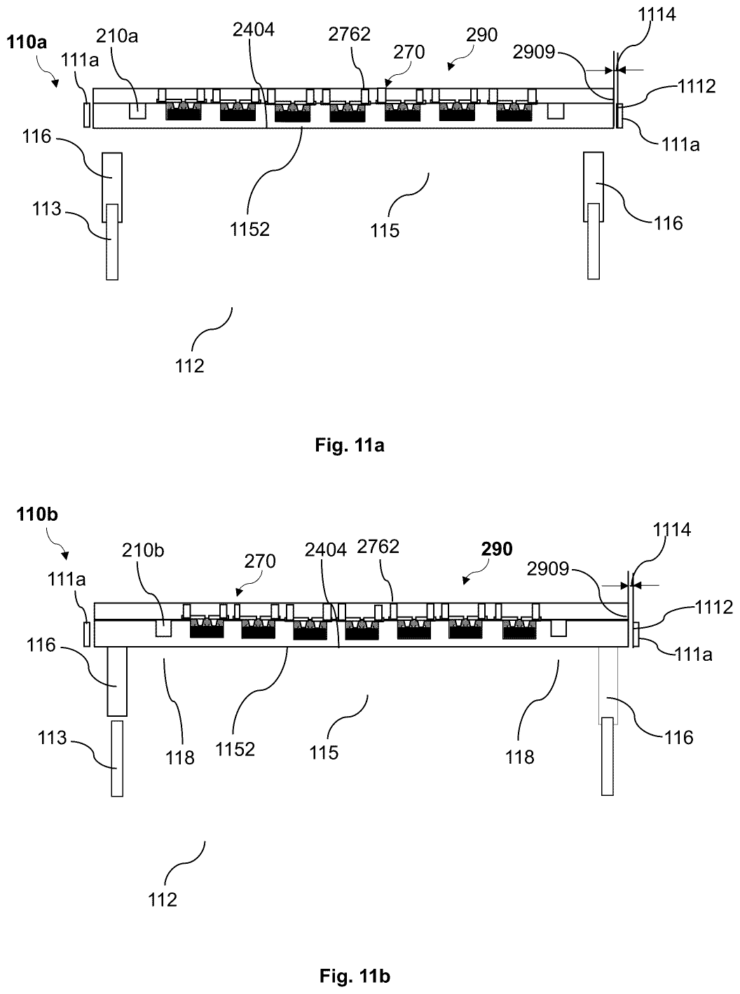

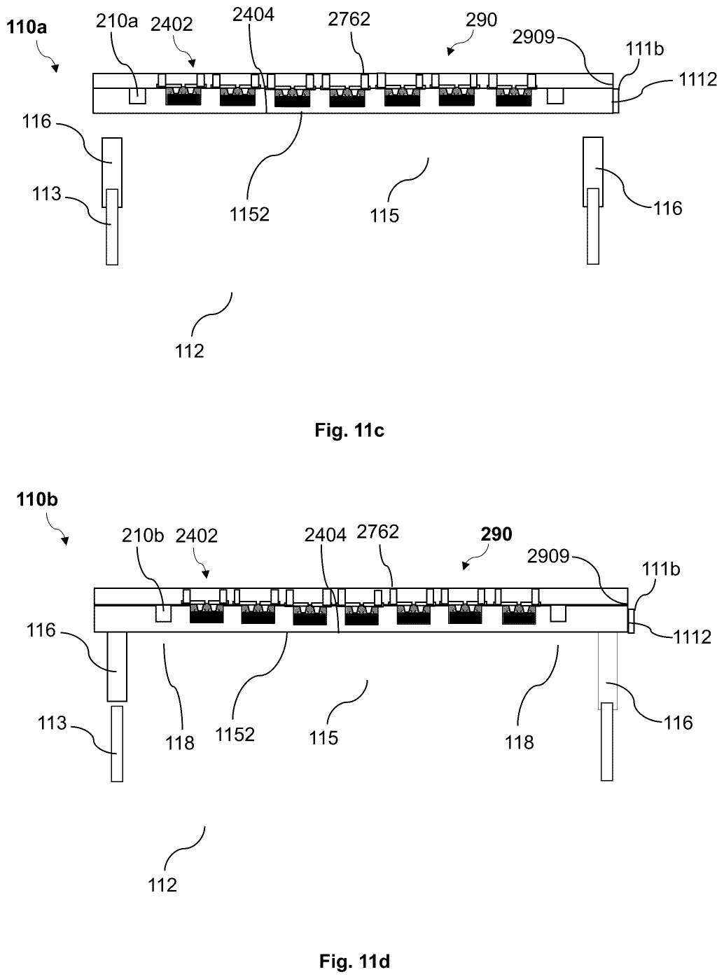

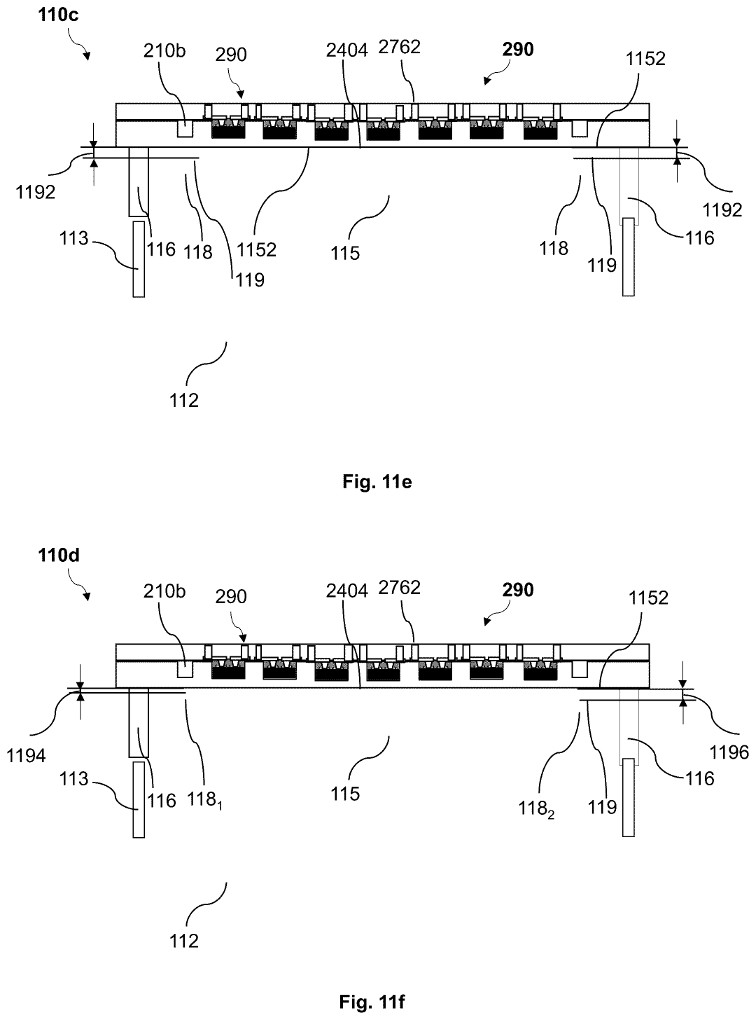

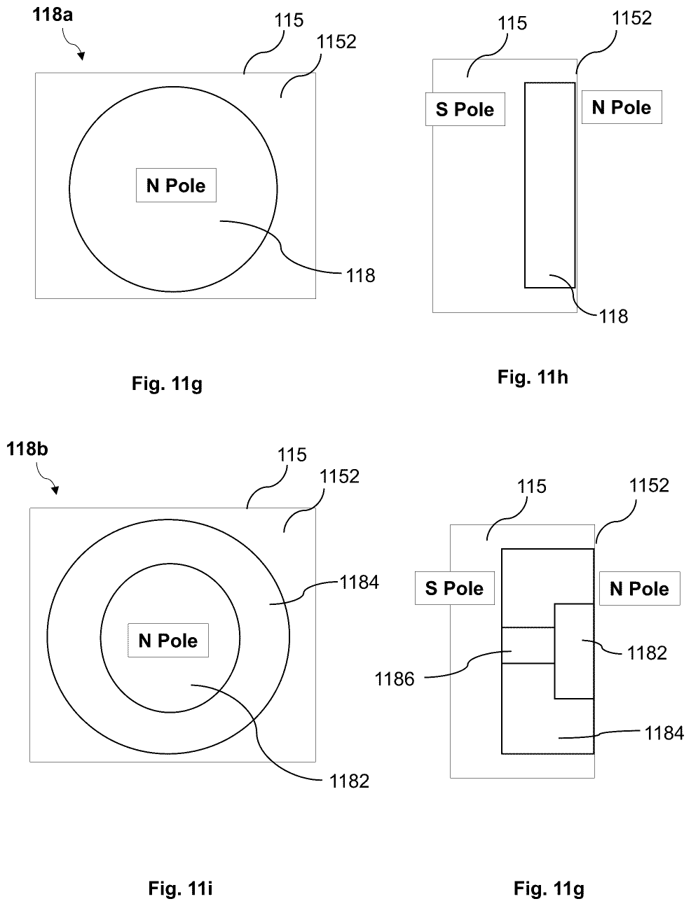

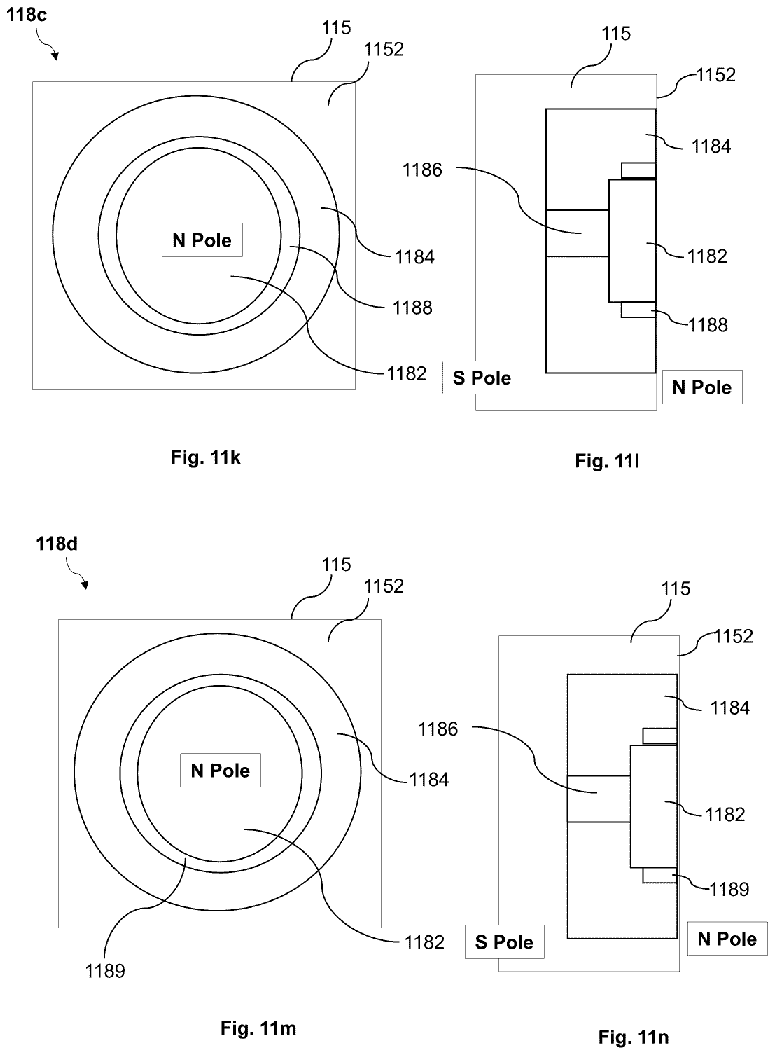

FIGS. 10a to 10d illustrates two exemplary embodiments of the solder ball attachment jig 110. FIG. 10a shows a cross-sectional view of a first embodiment 110a of the solder ball attachment jig 110. The first embodiment 110a has a platform 112 and a plate carrier 114 configured to be coupled to the platform 112 for carrying and fixing the reconstructed panel 290. The plate carrier 114 has a base plate 115 and one or more releasing holes 116 extending through the base plate 115; while the platform 112 has one or more ejectors 113 corresponding to the releasing holes 116 so that the ejector 113 is configured to be inserted through the releasing hole 116 for releasing the reconstructed panel 290 from the solder ball attachment jig 110. Accordingly, the ejector 113 and the releasing hole 116 has complementary configurations for forming a jig internal space 1102 for relative movement of the platform 112 towards or away from the plate carrier 114. The base plate 115 may be made of any material which could carry the reconstructed panel 290, including metals (such as Aluminum), alloys (such as Alloy 46), glass, ceramic or any combination thereof. FIG. 10a also shows that the first embodiment 110a has one or more locating features 111, such as confining pins 111a shown in FIGS. 11a & 11b or datum pins 111b shown in FIGS. 11c & 11d. The locating features 111 are located at edges 1156 of the base plate 115 for guiding the reconstructed panel 290 to be mounted onto a pre-determined position on the plate carrier 114. The locating feature 111 has an inner side 1112 facing inwardly to the releasing hole 116.

FIG. 10b shows a cross-sectional view of a second embodiment 110b of the solder ball attachment jig 110. The second embodiment 110b has a similar structure to the first embodiment 110a. However, compared with the first embodiment 110a, the second embodiment 110b further has one or more magnetic pins 118 corresponding to the warpage-preventing device 210 in the reconstructed panel 290. In a preferred embodiment, the magnetic pin 118 can be seen with a top surface 119 exposed from a top surface 1152 of the base plate 115; accordingly, the magnetic pin 118 can be used for guiding the reconstructed panel 290 to be mounted onto the plate carrier 114 in such a way that the warpage-preventing device 210 can be aligned with the magnetic pin 118. In an embodiment, the top surface 119 of the magnetic pin 118 is co-planar with the top surface 1152 of the base plate 115. The magnetic pin 118 may be made of any magnetic material for generating the magnetic force between the magnetic pin 118 and the warpage-preventing device 210. Therefore, both the locating feature 111 and the magnetic pin 118 can be used for guiding the reconstructed panel 290 to be mounted onto the pre-determined position on the plate carrier 114 for the second embodiment 110b. For example, the locating feature 111 may provide a rough guidance first; and then the magnetic pin 118 may provide a precise guidance by aligning the warpage-preventing devices 210 to the magnetic pins 118 respectively.

FIG. 10c shows a top side view of the second embodiment 110b of the solder ball attachment jig 110. The releasing holes 116 are made at peripheries 1154 of the base plate 115; and the magnetic pin 118 are made near to the locating feature 111 at the edges 1156 of the base plate 115. In a preferred embodiment, the locating feature 111, the releasing hole 116 and the magnetic pins 118 are symmetrically arranged on the base plate 115. FIG. 10d shows a magnified view of the plate carrier 114 where the locating feature 111 and the edges 1156 are imaginarily removed at a cross-section A-A (as indicated by the dash line) in FIG. 10c for easy illustration. The ejector 113 and the releasing hole 116 would have complementary configurations for the ejector 113 to be inserted into the releasing hole 116. For example, as shown in FIG. 10d, the ejector 113 has a rod-like configuration complementary to a hollow cylindrical configuration of the releasing hole 116. It is understood that the ejector 113 and the releasing hole 116 may have other complementary configurations which are also within the scope of present disclosure.

FIGS. 11a to 11n illustrate Step S14 of the method S10, mounting the reconstructed panel 290 onto the solder ball attachment jig 110. FIG. 11a shows a cross-sectional view that the reconstructed panel 290 is mounted onto the first embodiment 110a of the solder ball attachment jig 110 in a face-up manner, i.e., the back side 2404 of the molded panel 240 is in contact with the top surface 1152 of the base plate 115; while the circuit layer 270 of the reconstructed panel 290 faces away from the base plate 115. In the first embodiment 110a, the warpage-preventing device 210 includes dummy dies 210a (such as Silicon blocks) surrounding the semiconductor die 200, so that a gravity force of the dummy dies 210a (such as Silicon blocks) would balance the semiconductor dies 200 for preventing warpage of the reconstructed panel 290. In a preferred embodiment, the dummy dies 210a has a size comparable to that of the semiconductor dies 200. In a more preferred embodiment, the dummy dies 210a has a same size as that of the semiconductor dies 200. In addition, the first embodiment 110a has the confining pins 111a as the locating features 111 for guiding the reconstructed panel 290 to be mounted onto the pre-determined position on the plate carrier 114. Particularly, the reconstructed panel 290 is mounted between the confining pins 111a with a distance 1114 between the inner side 1112 of the confining pin 111a and the reconstructed panel edge 2909 of the reconstructed panel 290. It is also shown that the confining pins 111a have a height smaller than a thickness of the reconstructed panel 290 for conveniently mounting the reconstructed panel 290 onto the plate carrier 114.

FIG. 11b shows a cross-sectional view that the reconstructed panel 290 is mounted onto the second embodiment 110b of the solder ball attachment jig 110 in the face-up manner as described in FIG. 11a. In the second embodiment 110b, the warpage-preventing device 210 includes metal shims 210b surrounding the semiconductor die 200, so that a magnetic force between the warpage-preventing device 210 and the magnetic pin 118 would balance the semiconductor die 200 for preventing warpage of the reconstructed panel 290. Preferably, the reconstructed panel 290 are aligned to the plate carrier 114 in such a way that the warpage-preventing device 210 and the magnetic pin 118 correspond to each other for maximizing the magnetic force. The metal shims 210b may be made of any material which could have magnetic force with the magnetic pin 118. In a preferred embodiment, the metal shims 210b include an alloy material of low coefficient of thermal expansion (CTE) to be compatible with the molding compound forming the molding layer 242. For example, the metal shim 210b is made of Alloy 46 with a CTE in a range of 7 to 11 ppm/° C., and preferably a CTE of around 7.8 ppm/° C.; while the molding layer 242 is made of G730 with the CTE of around 7.0 ppm/° C. Therefore, the metal shim 210b would not be shifted in the molding layer 242 beyond tolerance during heating and cooling of the molding process. In another embodiment, the metal shim 210b includes Copper (Cu) if the circuit layer 270 is also made of Copper (Cu). Similarly, the second embodiment 110b also has the confining pins 111a as the locating features 111 for guiding the reconstructed panel 290 to be mounted onto the pre-determined position on the plate carrier 114, with the distance 1114 between the inner side 1112 of the confining pin 111a and the reconstructed panel edges 2909 of the reconstructed panel 290. Similarly, it is also shown that the height of the confining pins 111a is smaller than the thickness of the reconstructed panel 290 for conveniently mounting the reconstructed panel 290 onto the plate carrier 114.

Similar to FIG. 11a, FIG. 11c shows a cross-sectional view of the reconstructed panel 290 mounted onto the first embodiment 110a of the solder ball attachment jig 110, except that the datum pin 111b, instead of the confining pins 111a is used as the locating feature 111. In contrast to the confining pin 111a, the inner side 1112 of the datum pin 111b is in contact with the reconstructed panel edge 2909 of the reconstructed panel 290. Similar to FIG. 11b, FIG. 11d shows a cross-sectional view of the reconstructed panel 290 mounted onto the second embodiment 110b of the solder ball attachment jig 110, except that the datum pin 111b is used as the locating feature 111 with the inner side 1112 in contact with the reconstructed panel edge 2909 of the reconstructed panel 290. The solder ball attachment jig 110 may have one datum pin 111b at either one edge 1156 of the base plate 115 for the first embodiment 110a and the second embodiment 110b (as shown in FIGS. 11c & 11d). Alternatively, the solder ball attachment jig 110 may have two or more datum pins 111b where the datum pins 111b can be adjusted according to the size of the reconstructed panel 290. Similar to the confining pins 111a, the datum pin 111b also has a height smaller than the thickness of the reconstructed panel 290 for conveniently mounting the reconstructed panel 290 onto the plate carrier 114. The locating features 111 (such as the confining pins 111a or the datum pin 111b) are skipped in the following drawings for easy illustration.

FIG. 11e shows a cross-sectional view of a third embodiment 110c of the solder ball attachment jig 110. The third embodiment 110c is similar to the second embodiment 110b except that the magnetic pin 118 in FIG. 11e is embedded inside the base plate 115. Therefore, the magnetic force between the magnetic pin 118 and the metal shim 210b for the third embodiment 110c is weaker than that for the second embodiment 110b shown in FIG. 11b, so that the reconstructed panel 290 can be more easily detached away from the third embodiment 110c in the releasing station 170. A depth 1192 of the magnetic pin 118 is measured between the top surface 119 of the magnetic pin 118 and the top surface 1152 of the base plate 115. The larger the depth 1192 is, the weaker the magnetic force between the magnetic pin 118 and the metal shim 210b would be. Therefore, the magnetic force would be conveniently controlled and adjusted by altering the depth 1192.

FIG. 11f shows a cross-sectional view of a fourth embodiment 110d of the solder ball attachment jig 110 where both a first magnetic pin 118₁ and a second magnetic pin 118₂ are embedded inside the base plate 115. However, a first depth 1194 of the first magnetic pin 118₁ is measured between the top surface 119 of the first magnetic pin 118₁ and the top surface 1152 of the base plate 115; while a second depth 1196 of the second magnetic pin 118₂ is measured between the top surface 119 of the second magnetic pin 118₂ and the top surface 1152 of the base plate 115. If the first depth 1194 is smaller than the second depth 1196, then the magnetic force between the metal shim 210b and the first magnetic pin 118₁ is stronger than that between the metal shim 210b and the second magnetic pin 118₂. Therefore, the magnetic force can be controlled along the plate carrier 114 for better preventing the warpage of the reconstructed panel 290. For example, if more semiconductor die 200 are bonded near to one side of the first carrier 220 (such as an area around the first magnetic pin 118₁), then the warpage would be more severe on that side, so a stronger magnetic force should be generated on that side to prevent the more severe warpage, such as by adopting magnetic pin 118 at the first depth 1194 beneath the top surface 1152 of the base plate 115 or even by adopting the magnetic pin 118 exposed from the top surface 1152 of the base plate 115 for the second embodiment 110b as shown in FIG. 11b for achieving the strongest magnetic force.

FIG. 11g to FIG. 11n shows 4 embodiments of the magnetic pin 118. FIGS. 11g & 11h show a top view and a cross-sectional view of a first embodiment 118a. The first embodiment 118a has a solid cylindrical configuration and may be made of any magnetic materials such as Cobalt magnet. FIG. 11g shows a north (N) pole of the first embodiment 118a at the top surface 1152 of the base plate 115; and FIG. 11h shows a south(S) pole opposed to the N pole. FIGS. 11i & 11j show a top view and a cross-sectional view of a second embodiment 118b with the N pole and the S pole. The second embodiment 118b has a core part 118₂ with a cylindrical configuration and a base part 1184 with a hollow cylindrical configuration surrounding the core part 118₂. The core part 118₂ may be made of any magnetic materials such as rare earth magnet; and the base part 1184 may be made of a structural steel such as SUM24L for providing a structural support to the core part 118₂. In addition, the second embodiment 118b also has a back cavity 1186 as a crew hole for tightening the magnetic pin 118 to the base plate 115.

FIGS. 11k & 11l show a top view and a cross-sectional view of a third embodiment 118c with the N pole and the S pole. In addition to the core part 118₂ and the base part 1184, the third embodiment 118c also has a front cavity 1188 between the core part 118₂ and the base part 1184. The core part 118₂ may be made of any magnetic materials such as Cobalt magnet; and the base part 1184 may be made of structural steel such as SUM24L for providing the structural support to the core part 118₂. The front cavity 1188 surrounds the core part 118₂ for confining the magnetic force within the core part 118₂ and not extending to the base part 1184.

FIGS. 11m & 11n show a top view and a cross-sectional view of a fourth embodiment 118d with the N pole and the S pole. The fourth embodiment 118d has a similar structure with the third embodiment 118c. However, the fourth embodiment 118d has a sandwiched part 1189 between the core part 118₂ and the base part 1184, instead of the front cavity 1188. Similarly, the core part 118₂ may be made of any magnetic material, such as a cobalt magnet or an alnico magnet; and the base part 1184 may be made of structural steel, such as SUM24L, to provide the structural support to the core part 118₂. The sandwiched part 1189 has a similar function of the front cavity 1188 for confining the magnetic force. The sandwiched part 1189 is made of non-magnetic materials including copper, zinc or its composites such as Brass. Since the sandwiched part 1189 has a stronger magnetic resistance than that of the front cavity 1188, the fourth embodiment 118d could strengthen the confinement of the magnetic force and thus provide a stronger magnetic force with the warpage-preventing device 210, compared with the front cavity 1188. In addition, the 4 embodiments 118a to 118d may have a surface treatment layer (not shown) such as an electroless plated nickel at the top surface 1152 of the base plate 115 (N pole) for a rust-prevention purpose. It is understood that the 4 embodiments 118a to 118d are exemplary only and all other variations are within the scope of the present disclosure.

The reconstructed panel 290 should be mounted as precisely as possible to its designed location on the solder ball attachment jig 110 by any means possible. For example, guidance may be provided by the locating features 111 (such as the confining pins 111a or the datum pin 111b), the top surface 119 of the magnetic pin 118 exposed from the base plate 115, or a combination thereof as described above. For another example, the base plate 115 and the reconstructed panel 290 has a same shape and the base plate 115 has a dimension just slightly larger than that of the reconstructed panel 290, so that the reconstructed panel 290 could not be mounted to other locations than its designed location on the base plate 115. It is understood that other means of locating the reconstructed panel 290 onto its designed location on the base plate 115 are also within the scope of the present disclosure.

FIGS. 12a to 12i illustrate Step S16 of the method S10 with the solder ball attachment system 100, attaching the solder balls 292 onto the reconstructed panel 290. To simplify illustration of the Step S16 described herein, only the first embodiment 110a of the solder ball attachment jig 110 will be shown, but it is understood that the following description is also applicable to the second embodiment 110b of the solder ball attachment jig 110. The platform 112 of the solder ball attachment jig 110 is also skipped for the illustration.

FIG. 12a shows a cross-sectional view that flux 294 is applied to (as indicated by the arrows) the reconstructed panel 290 in the flux station 120 of the solder ball attachment system 100 so that the flux 294 remains at the top stud surface 2762 of the studs 276. The application of the flux 294 may be done by any known technologies, such as flux printing. It is noted that the application of the flux 294 may be controlled according to a stud pattern of the studs 276. The stud pattern is a portion of a circuit pattern of the circuit layer 270 which may vary according to the design of a particular IC chip and the required placement of the solder balls 292 to make electrical connections to the external devices such as PCB. The top stud surface 2762 of the studs 276 may perform as Under Bump Metallization (UBM) pads for making the BGA semiconductor packages.

Then, the reconstructed panel 290 and the solder ball attachment jig 110 are conveyed by the conveyor 190 to the placement station 130 of the solder ball attachment system 100 for attaching the solder balls 292 to the flux 294 at the top stud surface 2762 of the studs 276 as shown in the cross-sectional view of FIG. 12b. Since the solder balls 292 and the flux 294 have chemical affinities, the solder balls 292 would be more securely attached to the reconstructed panel 290 with the application of the flux 294. Accordingly, the application of the solder balls 292 may also be controlled according to the stud pattern of the studs 276.

Then, the reconstructed panel 290 is conveyed by the conveyor 190 to the inspection station 140 for inspecting whether the solder balls 292 are correctly placed at the top stud surface 2762 of the studs 276. FIG. 12c shows a cross-sectional view of the reconstructed panel 290 with the solder balls 292. Abnormal scenarios of the solder balls 292 would be corrected in the inspection station 140. For example, if deviated from the top stud surface 2762 of the studs 276, the particular solder ball 292 would be adjusted to its correct position. If missing, the particular solder ball 292 would be dropped at the top stud surface 2762 of the studs 276 (as shown in FIG. 12c) either manually or automatically. If excessive, the particular solder ball 292 would be removed from the reconstructed panel 290. FIG. 12d shows a magnified cross-sectional view of a dashed square in FIG. 12c. It is shown that the solder ball 292 remains with the flux 294 at the top stud surface 2762 of the studs 276. Particularly, the solder ball 292 is still kept as a spherical configuration with a bottom portion 2922.

After the inspection and maybe the correction, the reconstructed panel 290 with the solder balls 292 is conveyed by the conveyor 190 to the reflow station 150 for reflowing (i.e., melting and fusing) the solder balls 292 to the top stud surface 2762 of the studs 276 at an elevated temperature. FIG. 12e shows a cross-sectional view of the reconstructed panel 290 with the reflowed solder balls 292. FIG. 12f shows a magnified cross-sectional view of a dashed square in FIG. 12e. It is shown that the bottom portion 2922 of the solder balls 292 is melted and fused with the studs 276 at the top stud surface 2762. Finally, after being cooled from the elevated temperate, the reconstructed panel 290 is conveyed by the conveyor 190 to the cleaning station 160 for removing the residual flux 294 from the reconstructed panel 290. A final inspection may be performed to the reconstructed panel 290 in the cleaning station 160. However, in contrast to the inspection performed in the inspection station 140, any abnormal scenario of the solder balls 292 cannot be corrected in the cleaning station 160. FIG. 12g shows a cross-sectional view of the reconstructed panel 290 with the solder balls 292 after the final inspection and the cleaning in the cleaning station 160. FIG. 12h shows a magnified cross-sectional view of a dashed square in FIG. 12g. It is shown that the residual flux 294 is removed from the solder balls 292 at the top stud surface 2762 of the studs 276.

FIG. 12i shows a cross-sectional view that the solder balls 292 is formed as described above on the alternative embodiment of the reconstructed panel 290 shown in FIG. 8b. The bottom portion 2922 of the solder balls 292 would melt and flow into the cavities 282 (as indicated by a dashed rectangle); and then would fuse at the top stud surface 2762 of the studs 276 during the reflow process. Therefore, the solder balls 292 could be more firmly secured at the studs 276 and would not shift or lost away from the reconstructed panel 290, which would significantly enhance reliability of the fan-out or fan-in semiconductor packages connected to the external devices such as PCB.

Next, the reconstructed panel 290 with the solder balls 292 is conveyed by the conveyor 190 to the releasing station 170. FIGS. 13a to 13c illustrates Step S18 of the method S10 with the solder ball attachment system 100, releasing the reconstructed panel 290 and the solder balls 292 from the solder ball attachment jig 110. FIG. 13a shows a cross-sectional view that the reconstructed panel 290 and the solder balls 292 may be released by the solder ball attachment jig 110 and a vacuum chunk 172 both of which work in conjunction to release the reconstructed panel 290. The solder ball attachment jig 110 has an ejector motor 117 for moving the ejector 113 upwardly through the releasing hole 116 until the ejector 113 is in contact with the back side 2404 of the molded panel 240. Then, the ejector motor 117 further drives the ejector 113 to move upwardly for pushing the reconstructed panel 290 at the back side 2404 of the molded panel 240 to move the reconstructed panel 290 upwardly while the plate carrier 114 of the solder ball attachment jig 110 is kept in place without movement. Meanwhile, the vacuum chunk 172 also pulls the reconstructed panel 290 upwardly using a vacuum force for moving the reconstructed panel 290 from the plate carrier 114. As a result, the reconstructed panel 290 with the solder balls 292 is detached and released from the solder ball attachment jig 110. Preferably, the solder ball attachment jig 110 pushes the reconstructed panel 290 upwardly and the vacuum chunk 172 pulls the reconstructed panel 290 upwardly at a same speed for better releasing the reconstructed panel 290 with the solder balls 292 from the solder ball attachment jig 110.

FIG. 13b shows a cross-sectional view that the reconstructed panel 290 with the solder balls 292 is completely released from the solder ball attachment jig 110 and held by the vacuum chunk 172. The ejector motor 117 moves the ejector 113 downwardly so that the solder ball attachment jig 110 goes back to a standby position waiting to receive a new reconstructed panel for repeating the processes as described above. FIG. 13c shows a cross-sectional view that the vacuum chunk 172 moves the reconstructed panel 290 with the solder balls 292 to the transferring station 180 for transferring the reconstructed panel 290 with the solder balls 292 to the wafer ring 182 with a dicing tape 184 for singulation. After turning off the vacuum force, the vacuum chunk 172 would not hold the reconstructed panel 290 anymore; and the reconstructed panel 290 with the solder balls 292 would be loaded onto the dicing tape 184 of the wafer ring 182. Then, the vacuum chunk 172 would move back to the releasing station 170 to pull and hold the new reconstructed panel with the solder ball attachment jig 110.

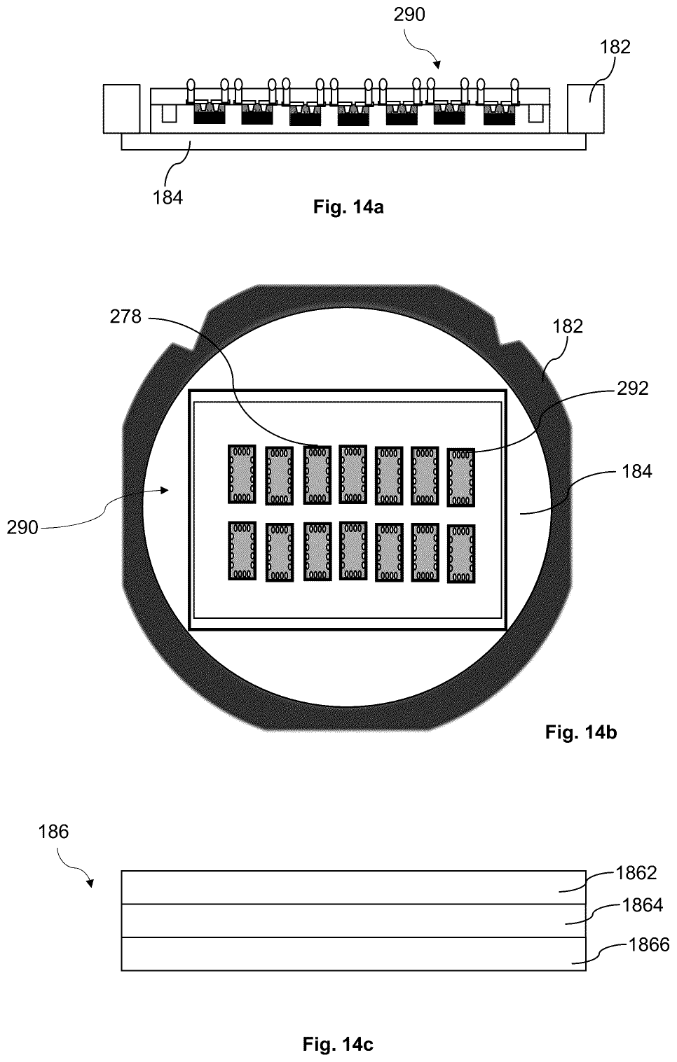

FIGS. 14a to 14c illustrates Step S20 of the method S10 with the solder ball attachment system 100, singulating the reconstructed panel 290 and the solder balls 292 into discrete semiconductor packages 300. FIG. 14a shows a cross-sectional view of the wafer ring 182 with the dicing tape 184 holding the reconstructed panel 290 and the solder balls 292. The dicing tape 184 has strength or adhesivity to secure the reconstructed panel 290 and the discrete semiconductor packages 300 in place during the singulation. FIG. 14b shows a top view that the reconstructed panel 290 and the solder balls 292 are held by the dicing tape 184 and the wafer ring 182. The circuit profile 278 is also shown for indicating locations in the reconstructed panel 290 of the discrete semiconductor packages 300 that would be singulated into.

The dicing tape 184 may be any adhesive tape suitable for the purpose of holding and securing the reconstructed panel 290 during the singulation, as well as releasing the discrete semiconductor packages 300 from the dicing tape 184 after the singulation. In an embodiment, the dicing tape 184 may be an ultraviolet (UV) adhesive tape which would lose securing strength or adhesivity under UV light. Therefore, the discrete semiconductor packages 300 would be detached from the dicing tape 184 after the singulation by exposing the dicing tape 184 to the UV light. FIG. 14c shows a cross-sectional view of a UV curable tape 186 as an embodiment of the UV adhesive tape. The UV curable tape 186 has a sandwiched structure with a base film 1862, an adhesive layer 1864 and a polymer film 1866. The base film 1862 may be a polyolefin film; the adhesive layer 1864 may be an acrylic-UV curable layer; and the polymer film 1866 may be a polyester film. Accordingly, the acrylic-UV curable layer as the adhesive layer 1864 would lose adhesivity under the UV light for releasing the discrete semiconductor packages 300 after the singulation.

FIGS. 15a to 15c illustrates the Step S20 of the S10, singulating the reconstructed panel 290 and the solder balls 292 into the discrete semiconductor packages 300. FIG. 15a shows a cross-sectional view of the singulation with a saw blade 310 along saw streets 312. The discrete semiconductor packages 300 includes one or more semiconductor dies 200 encapsulated in the molded panel 240, the circuit layer 270 encapsulated in the dielectric layer 280 and the solder balls 292 for electrical connections to external devices such as PCB. Accordingly, the semiconductor die 200 is electrically led out through the filled vias 2005, the circuit layer 270 (including the RDL 272 and the stud layer 274) and the solder balls 292 to external devices such as PCB. If the discrete semiconductor package 300 include two or more semiconductor dies 200, the circuit layer 270 would electrically couple the two or more semiconductor dies 200 for communicating internal signals; and therefore, the discrete semiconductor package 300 would work as a multiple chip module (MCM). For example, an MCM is shown in a dotted rectangle in FIG. 15a by including 2 semiconductor dies 200.

FIG. 15b shows a magnified cross-sectional view of singulating the reconstructed panel 290 and the solder balls 292 into the discrete semiconductor package 300 on the dicing tape 184. The dicing tape 184 has a total thickness 1842 such as 150 micrometers (μm). During the singulation, the saw blade 310 would cut a top thickness 1844 of the dicing tape 184 to make sure that the reconstructed panel 290 are completely separated; and meanwhile the remaining dicing tape 184 could still have enough strength to hold the discrete semiconductor packages 300. Preferably, the top thickness 1844 is around one third of the total thickness 1842 of the dicing tape 184. So, the top thickness 1844 of around 50 micrometers (μm) would be cut away for the total thickness 1842 of 150 total thickness 1842 during the singulation.

FIG. 15c shows a top view that the reconstructed panel 290 with the solder balls 292 is singulated by the saw blade 310 along the saw streets 312 into the discrete semiconductor packages 300 as described above. The warpage-preventing device 210 can also be singulated and then detached from the dicing tape 184 for recycling purposes. The MCM is also shown in a dotted rectangle in FIG. 15c by including 2 semiconductor dies 200 as described in FIG. 15a.

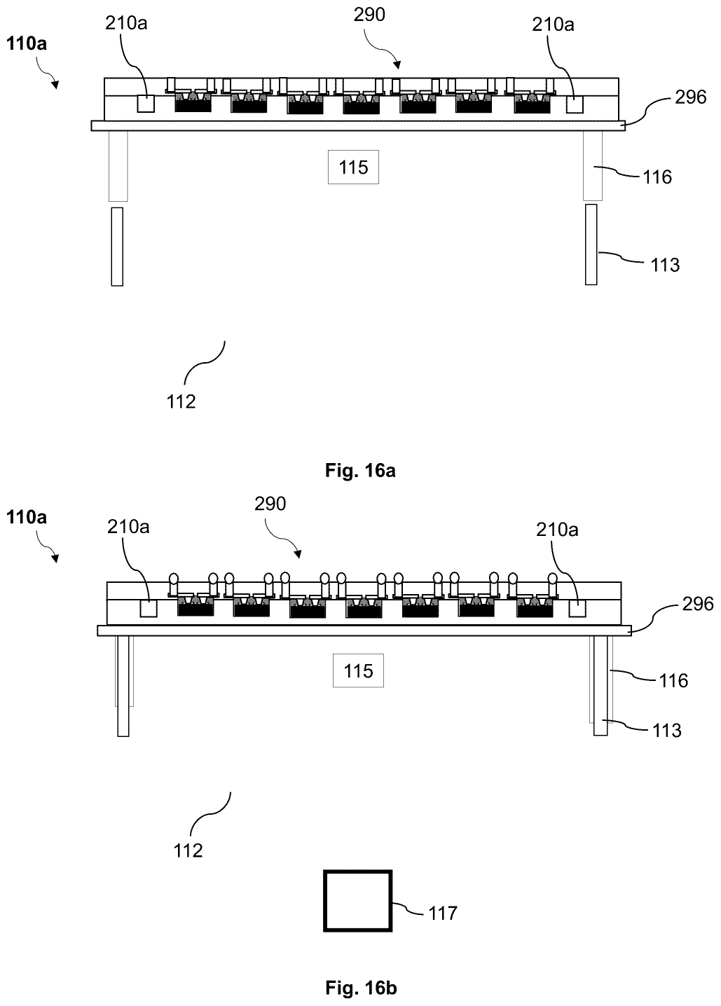

FIGS. 16a & 16b illustrates another embodiment of Step S14. FIG. 16a shows a cross-sectional view similar to FIG. 11a where dummy dies 210a are adopted for preventing the warpage. In addition to the dummy dies 210a, a double-sided adhesive tape 296 can be applied between the reconstructed panel 290 and the base plate 115 for providing an adhesive force for further minimizing or even eliminating the warpage of the reconstructed panel 290 during the attachment of the solder balls 292. FIG. 16b shows a cross-sectional view that the reconstructed panel 290 and the solder balls 292 can still be released by driving the ejector 113 through the releasing hole 116, since the double-sided adhesive tape 296 has a flexible nature and would not resist the upward movement of the ejector 113 to push the reconstructed panel 290 away from the plate carrier 114. The double-sided adhesive tape 296 would lose the adhesivity under certain conditions such as at an elevated temperature, being exposed to Ultraviolet (UV) light or a combination thereof, so that the reconstructed panel 290 can be released from the double-sided adhesive tape 296 under the certain conditions. For example, the double-sided adhesive tape 296 would be a high bump tape, a high temperate tape, a UV tape, or any combinations thereof. Alternatively, temporary adhesive coating may be adopted such as adhesive waxes, instead of the double-sided adhesive tape 296. The temporary adhesive coating could also lose adhesivity under some conditions for releasing the reconstructed panel 290 with the solder balls 292.

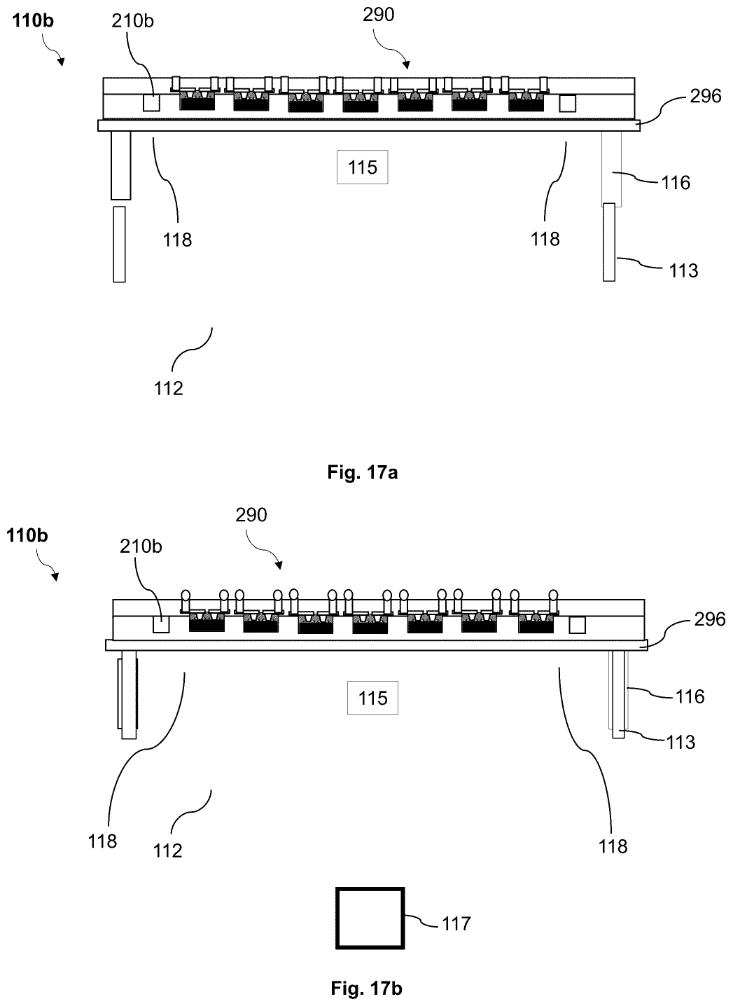

FIGS. 17a & 17b illustrates another embodiment of Step S14. FIG. 17a shows a cross-sectional view similar to FIG. 11b where the metal shims 210b are adopted for preventing the warpage. Similarly, in addition to the magnetic force between the metal shim 210b and the magnetic pin 118, the double-sided adhesive tape 296 can be also applied between the reconstructed panel 290 and the base plate 115 for providing the adhesive force for further minimizing or even eliminating the warpage of the reconstructed panel 290 during the attachment of the solder balls 292. FIG. 17b shows a cross-sectional view that the reconstructed panel 290 and the solder balls 292 can still be released by driving the ejector 113 through the releasing hole 116, as stated above since the double-sided adhesive tape 296 has the flexible nature and would not resist the upward movement of the ejector 113 to push the reconstructed panel 290 away from the plate carrier 114. As described above, the double-sided adhesive tape 296 would lose the adhesivity under certain conditions for releasing the reconstructed panel 290 with the solder balls 292.

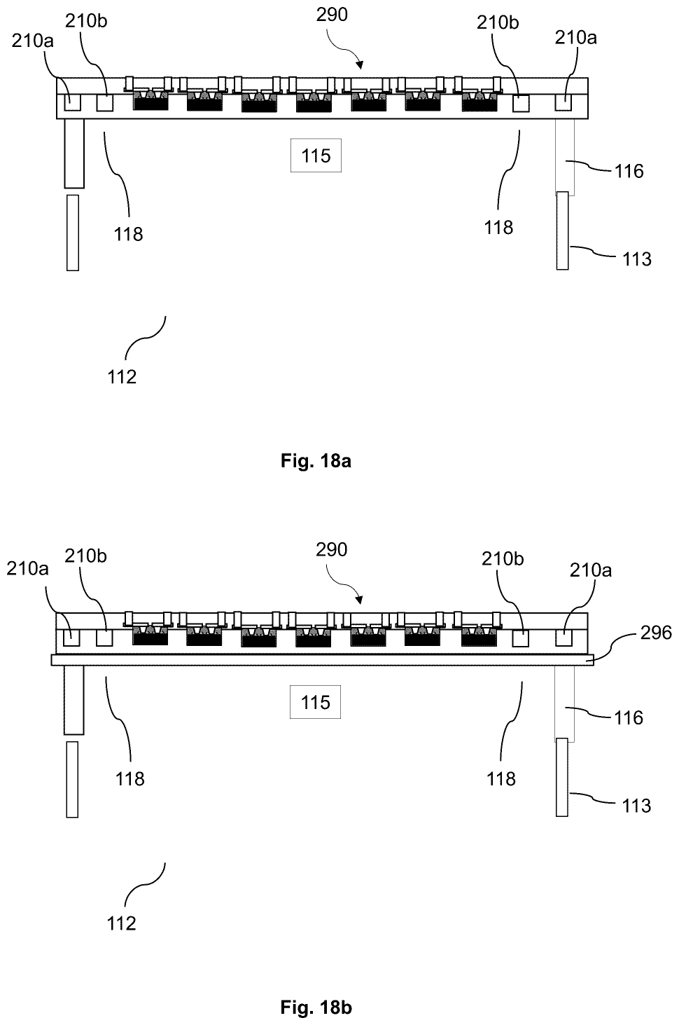

FIGS. 18a & 18b illustrate possible combinations of the embodiments as shown above. FIG. 18a shows a cross-sectional view of combining the embodiments shown in FIGS. 11a & 11b that the reconstructed panel 290 includes both the dummy dies 210a and the metal shims 210b, so that the warpage is prevented by both the gravity force from the dummy dies 210a and the magnetic force from the metal shim 210b and the magnetic pin 118. FIG. 18b shows a cross-sectional view of combing the embodiments shown in FIGS. 16a & 17a that the reconstructed panel 290 includes both the dummy dies 210a and the metal shims 210b while the double-sided adhesive tape 296 (or the temporary adhesive coating) is also applied, so that the warpage is further prevented by the adhesive force, in addition to the gravity force from the dummy dies 210a and the magnetic force from the metal shim 210b and the magnetic pin 118. It is understood that other combinations or variations for preventing the warpage of the reconstructed panel 290 are also within the scope of the present disclosure for the solder ball attachment.

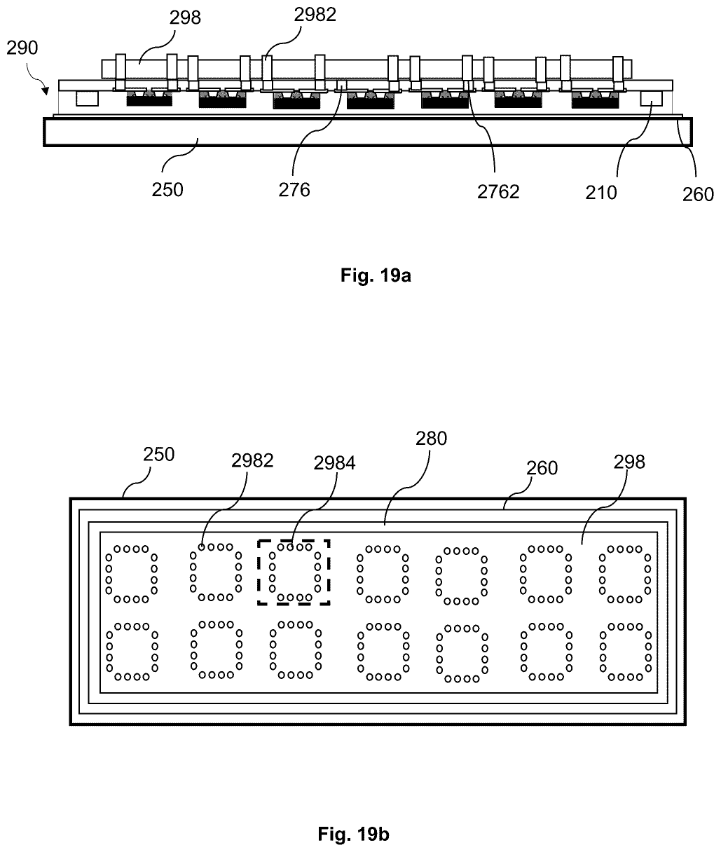

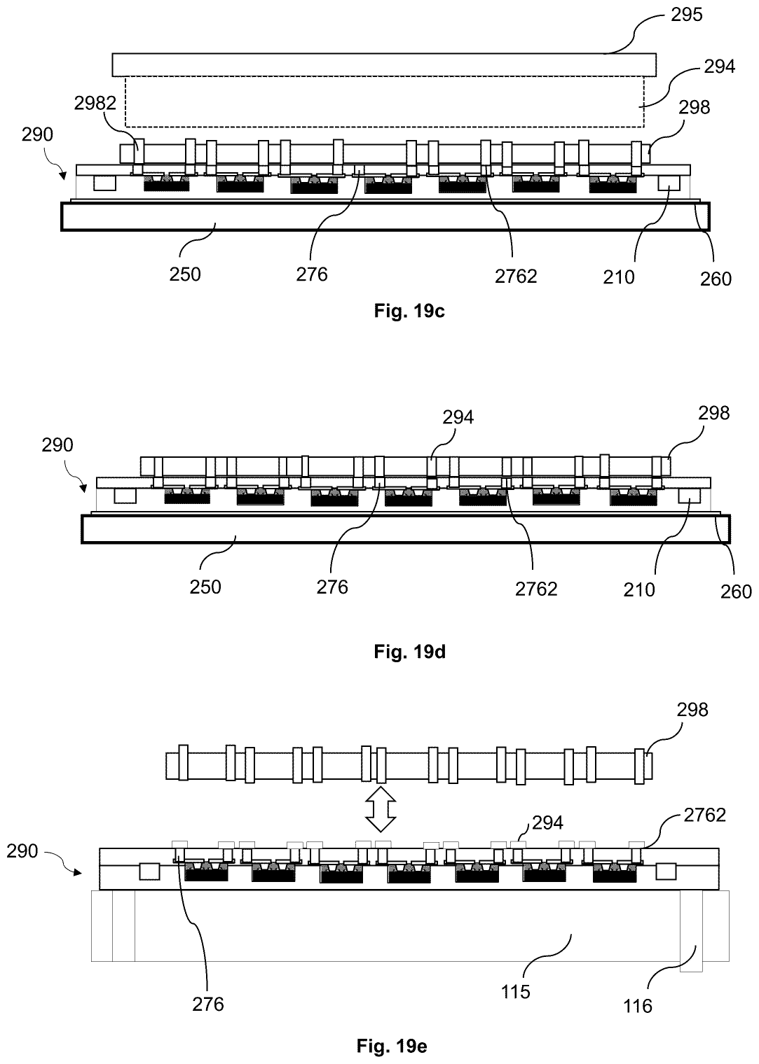

FIGS. 19a to 19e illustrate a process of applying the flux 294 to the reconstructed panel 290 in FIG. 12a. FIGS. 19a & 19b show a cross-sectional view and a top view that the flux station 120 has a flux mask 298 which could be placed onto the circuit layer 270 of the reconstructed panel 290. The flux mask 298 has mask openings 2982 corresponding to the exposed top stud surface 2762 the studs 276 respectively. In other words, the top stud surface 2762 of the studs 276 is exposed from the flux mask 298 through the mask openings 2982. Alternative to being placed on the reconstructed panel 290, the flux mask 298 may be suspended above the reconstructed panel 290 at a pre-determined height for facilitating the flux 294 to flow through the mask openings 2982 of the flux mask 298. Therefore, the flux mask 298 has a mask opening pattern 2984 (as indicated by the dashed square) which represents the stud pattern of the studs 276. The flux station 120 may have fixing mechanics for securing the flux mask 298 in place on or above the reconstructed panel 290 such as clamps.

FIG. 19c shows a cross-sectional view that the flux 294 is applied to the reconstructed panel 290 through the flux mask 298. Accordingly, the flux 294 could flow through the mask openings 2982 and arrive at the top stud surface 2762 of the studs 276. The flux station 120 may have a flux applicator 295 such as a squeegee for squeezing the flux 294 onto the reconstructed panel 290. FIG. 19d shows a cross-sectional view that the flux 294 fills in the mask openings 2982 of the flux mask 298 and then remains at the top stud surface 2762 of the studs 276. FIG. 19e shows a cross-sectional view that the flux mask 298 is removed from the reconstructed panel 290; and the flux 294 still remains at the top stud surface 2762 of the studs 276. In the following, the solder balls 292 are reflowed with the flux 294 at the top stud surface 2762 of the studs 276 as shown in FIG. 19e.

In the application, unless specified otherwise, the terms “comprising”, “comprise”, and grammatical variants thereof, intended to represent “open” or “inclusive” language such that they include recited elements but also permit inclusion of additional, non-explicitly recited elements.

As used herein, the term “about”, in the context of concentrations of components of the formulations, typically means +/−5% of the stated value, more typically +/−4% of the stated value, more typically +/−3% of the stated value, more typically, +/−2% of the stated value, even more typically +/−1% of the stated value, and even more typically +/−0.5% of the stated value.

Throughout this disclosure, certain embodiments may be disclosed in a range format. The description in range format is merely for convenience and brevity and should not be construed as an inflexible limitation on the scope of the disclosed ranges. Accordingly, the description of a range should be considered to have specifically disclosed all the possible sub-ranges as well as individual numerical values within that range. For example, description of a range such as from 1 to 6 should be considered to have specifically disclosed sub-ranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

It will be apparent that various other modifications and adaptations of the application will be apparent to the person skilled in the art after reading the foregoing disclosure without departing from the spirit and scope of the application and it is intended that all such modifications and adaptations come within the scope of the appended claims.

### REFERENCE NUMERALS

100 solder ball attachment system;
110 solder ball attachment jig;
   110a first embodiment of the solder ball attachment jig;
   110b second embodiment of the solder ball attachment jig;
   110c third embodiment of the solder ball attachment jig;
   110d fourth embodiment of the solder ball attachment jig;
   1102 jig internal space;
111 locating feature;
   111a confining pin;
   111b datum pin;
   1112 inner side of the locating feature;
   1114 distance between the inner side of the locating feature and the edge of the reconstructed panel;
112 platform;
113 ejector;
114 plate carrier;
115 base plate;
   1152 top surface of the base plate;
   1154 peripheries of the base plate;
   1156 edges of the base plate;
116 releasing hole;
117 ejector motor;
118 magnetic pin;
   118a first embodiment of the magnetic pin;
   118b second embodiment of the magnetic pin;
      118₂ core part of the magnetic pin;
      1184 base part of the magnetic pin;
      1186 back cavity of the magnetic pin;
   118c third embodiment of the magnetic pin;
      1188 front cavity;
   118d fourth embodiment of the magnetic pin;
      1189 sandwiched part of the magnetic pin;
118₁ first magnetic pin;
118₂ second magnetic pin;
119 top surface of the magnetic pin;
1192 depth of the magnetic pin beneath the top surface of the base plate;
1194 first depth of the magnetic pin;
1196 second depth of the magnetic pin;
120 flux station;
130 placement station;
140 inspection station;
150 reflow station;
160 cleaning station;
170 releasing station
172 vacuum chunk;
180 transferring station;
182 wafer ring;
184 dicing tape;
   1842 total thickness;
   1844 top thickness;
186 UV curable tape;
   1862 polyolefin film;
   1864 acrylic-UV curable layer;
   1866 polyester film;
190 conveyor;
200 semiconductor die;
   2002 active surface;
   2004 pre-via;
   2005 filled vias;
      2005a filled top surface;
   2006 contact pad;
   2007 die profile;
   2008 inactive surface;
210 warpage-preventing device;
   2102 first warpage-preventing device;
   2104 second warpage-preventing device;
   2106 third warpage-preventing device;
210a dummy dies (such as Silicon blocks);
210b metal shims;
212 first surface of the warpage-preventing device;
214 crosses (as warpage-preventing device features);
220 first carrier;
   2202 front surface of the first carrier;
   2204 central location of the first carrier;
   2206 peripheries of the first carrier;
222 die bonding unit;
   2222 carrier mark;
   2224 die bonding unit profile;
224 warpage-preventing device bonding unit;
   2242 warpage-preventing carrier mark;
230 first heat release tape;
240 molded panel;
   2402 active side of the molded panel;
   2404 back side of the molded panel;
   2406 molded panel edge;
242 molded layer;
   2422 active surface of the molded layer;
   2424 back surface of the molded layer;
   2426 molded layer edges;
250 second carrier;
   2502 front surface of the second carrier;
260 second heat release tape;
270 circuit layer;
272 redistribution layer (RDL);
274 stud layer;
276 studs;
   2762 top stud surface of the studs;
278 circuit profile;
280 dielectric layer;
   2802 top dielectric surface of the dielectric layer;
   2804 bottom dielectric surface of the dielectric layer;
   2806 edges of the dielectric layer;
282 cavities;
290 reconstructed panel;
   2901 first dashed rectangle;
   2902 first portion of the reconstructed panel;
   2903 second dashed rectangle;
   2904 second portion of the reconstructed panel;
   2905 third dashed rectangle;
   2906 third portion of the reconstructed panel;
   2907 first separation street;
   2908 second separation street;
   2909 reconstructed panel edges;
292 solder ball;
   2922 bottom portion of the solder ball;
294 flux;
295 flux applicator;
296 double-sided adhesive tape;
298 flux mask;
   2982 mask openings;
   2984 mask opening pattern;
300 discrete semiconductor packages;
310 saw blade;
312 saw street;
320 package profile;

What is claimed is:

1. A method of preventing warpage in attaching solder balls for a panel-level semiconductor process, comprising:
forming a reconstructed panel having a warpage-preventing device;
mounting the reconstructed panel onto a solder ball attachment jig;
attaching the solder balls onto the reconstructed panel; and
releasing the reconstructed panel and the solder balls from the solder ball attachment jig,
wherein a warpage-preventing force is applied by the warpage-preventing device against the warpage of the reconstructed panel, and wherein the solder ball attachment jig comprises:
a platform having at least one ejector; and
a plate carrier having at least one releasing hole,
wherein the at least one ejector is configured to be inserted through the at least one releasing hole to release the reconstructed panel and the solder ball from the solder ball attachment jig.

2. The method of claim 1, wherein the warpage-preventing force includes a magnetic force, an adhesive force, a gravity force, or a combination thereof.

3. The method of claim 2, wherein the warpage-preventing device comprises at least one metal shim at peripheries of the reconstructed panel for providing the magnetic force between the at least one metal shim and the solder ball attachment jig.

4. The method of claim 2, wherein the warpage-preventing device comprises at least one dummy die at peripheries of the reconstructed panel for providing the gravity force.

5. The method of claim 2, further comprising: applying an adhesive tape onto the solder ball attachment jig before mounting the reconstructed panel, wherein the adhesive tape is configured to provide the adhesive force to the reconstructed panel.

6. The method of claim 1, further comprising:
applying flux to the reconstructed panel in a flux station;
placing the solder balls onto the flux and the reconstructed panel in a placement station;
inspecting the solder balls on the reconstructed panel in an inspection station;
reflowing the solder balls on the reconstructed panel in a reflow station;
removing the flux from the reconstructed panel in a cleaning station; and
releasing the reconstructed panel and the solder balls from the solder ball attachment jig in a releasing station,
wherein the reconstructed panel on the solder ball attachment jig is conveyed by a conveyor among the flux station, the placement station, the inspection station, the reflow station, the cleaning station and the releasing station.

7. The method of claim 1, further comprising: transferring the reconstructed panel and the solder balls from the solder ball attachment jig to a wafer ring and a dicing tape.

8. A solder ball attachment jig for preventing warpage of a reconstructed panel in a panel-level semiconductor process, comprising:
a platform having at least one ejector; and
a plate carrier operable to be coupled to the platform for carrying and fixing the reconstructed panel with a plurality of semiconductor dies and a warpage-preventing device, and the plate carrier further comprising a base plate and at least one releasing hole extending through the base plate,
wherein the at least one ejector is configured to be inserted through the at least one releasing hole for releasing the reconstructed panel from the solder ball attachment jig.

9. The solder ball attachment jig of claim 8, wherein the plate carrier further comprises a plurality of magnetic pins at peripheries of the base plate for providing a magnetic force with the warpage-preventing device of the reconstructed panel.

10. The solder ball attachment jig of claim 9, wherein the plurality of magnetic pins are exposed from the base plate.

11. The solder ball attachment jig of claim 9, wherein the plurality of magnetic pins are embedded inside the base plate.

12. The solder ball attachment jig of claim 8, further comprising an adhesive tape configured to be applied onto the base plate for providing an adhesive force against the warpage of the reconstructed panel.

13. The solder ball attachment jig of claim 8, further comprising a locating feature for aligning the reconstructed panel to the plate carrier of the solder ball attachment jig.

14. The solder ball attachment jig of claim 13, wherein the locating feature comprises one or more confining pins, wherein the confining pins are spaced from the reconstructed panel by a distance.

15. The solder ball attachment jig of claim 13, wherein the locating feature comprises a datum pin, wherein the datum pin is in contact with the reconstructed panel.

16. A solder ball attachment system for preventing warpage of a reconstructed panel in a panel-level semiconductor process, comprising:
a solder ball attachment jig, wherein the solder ball attachment jig further comprises:
a platform having at least one ejector; and
a plate carrier operable to be coupled to the platform for carrying and fixing the reconstructed panel with a plurality of semiconductor dies and a warpage-preventing device, and the plate carrier further comprising a base plate and at least one releasing hole extending through the base plate,
wherein the at least one ejector is configured to be inserted through the at least one releasing hole for releasing the reconstructed panel from the solder ball attachment jig;
a flux station for applying flux to the reconstructed panel;
a placement station for placing solder balls to the reconstructed panel;
an inspection station for inspecting the solder balls on the reconstructed panel;
a reflow station for reflowing the solder balls on the reconstructed panel;
a cleaning station for removing the flux from the reconstructed panel;
a releasing station for releasing the reconstructed panel and the solder balls from the solder ball attachment jig; and
a conveyor for conveying the reconstructed panel on the solder ball attachment jig among the flux station, the placement station, the inspection station, the reflow station, the cleaning station and the releasing station.

17. The solder ball attachment system of claim 16, further comprising a transferring station for transferring the reconstructed panel and the solder balls from the solder ball attachment jig to a wafer ring and a dicing tape.

18. The solder ball attachment system of claim 16, wherein the releasing station further comprising a vacuum chunk to work in conjunction with the solder ball attachment jig for releasing the reconstructed panel from the solder ball attachment jig.

19. The solder ball attachment system of claim 18, wherein the vacuum chunk and the ejectors move the reconstructed panel at a same speed.

20. The solder ball attachment system of claim 16, wherein the solder ball attachment jig further comprises a locating feature for aligning the reconstructed panel to the plate carrier of the solder ball attachment jig.
